(19) United States
(12) Patent Application Publication
(10) Pub. No.: US 2026/0154473 A1
(43) Pub. Date: Jun. 4, 2026

(54) METHOD FOR PREVENTATIVE MAINTENANCE FORECASTING OF REFRIGERATION SYSTEMS

(71) Applicant: Axiom Cloud Inc., San Jose, CA (US)

(72) Inventors: Adam Graham, Los Angeles, CA (US); Amrit Robbins, San Jose, CA (US); Junghee Kim, Yorba Linda, CA (US); James Wheatley, Longview, TX (US); Kyle Eastwood, Phelan, CA (US); Katelyn Stone, Kent, WA (US); Michelle Kim, Charlottesville, VA (US); Matthew Conrad Nigro, Bedford, NH (US); Patrick Castles, Los Angeles, CA (US); Steven Stonaker, New Orleans, LA (US); Juliana Campos Parajeles, San Carlos (CR); Sofía Galán Bataller, San Francisco, CA (US); Robert Leffler, Portland, ME (US)

(21) Appl. No.: 19/406,513

(22) Filed: Dec. 2, 2025

Related U.S. Application Data
(60) Provisional application No. 63/726,869, filed on Dec. 2, 2024.

(51) Int. Cl. G06F 30/20

(52) U.S. Cl. CPC G06F 30/20; G05B 23/0283

(57) ABSTRACT

A method includes: deriving a set of operational states of a refrigeration system based on combinations of actuator positions; accessing a set of timeseries sensor data captured by sensors associated with a refrigeration system; accessing a set of refrigeration system rules specifying nominal behavior of refrigeration components in distinct operational states; generating a set of forecast sensor data representing predicted behavior of the refrigeration system in operational states based on a segment of timeseries sensor data, representing the operational state, and the set of refrigeration system rules; detecting a deviation, in a set of forecast sensor data representing predicted behavior of the refrigeration system in an operational state, from nominal thermodynamic behavior of refrigeration components in the operational state; detecting a refrigeration component associated with the deviation according to a graph of the refrigeration system; and flagging the refrigeration component for inspection prior to predicted onset of the deviation.

### CROSS-REFERENCE TO RELATED APPLICATIONS

This Application claims the benefit of U.S. Provisional Application No. 63/726,869, filed on 2 Dec. 2024, which is incorporated in its entirety by this reference.

### TECHNICAL FIELD

This invention relates generally to the field of refrigeration systems and more specifically to a new and useful method for preventative maintenance forecasting of refrigeration systems in the field of preventative maintenance of refrigeration systems.

### BRIEF DESCRIPTION OF THE FIGURES

FIG. 1 is a flowchart representation of a method;

FIG. 2 is a flowchart representation of one variation of the method;

FIG. 3 is a flowchart representation of one variation of the method;

FIG. 4 is a flowchart representation of one variation of the method; and

FIG. 5 is a flowchart representation of one variation of the method.

### DESCRIPTION OF THE EMBODIMENTS

The following description of embodiments of the invention is not intended to limit the invention to these embodiments but rather to enable a person skilled in the art to make and use this invention. Variations, configurations, implementations, example implementations, and examples described herein are optional and are not exclusive to the variations, configurations, implementations, example implementations, and examples they describe. The invention described herein can include any and all permutations of these variations, configurations, implementations, example implementations, and examples.

### 1. Method

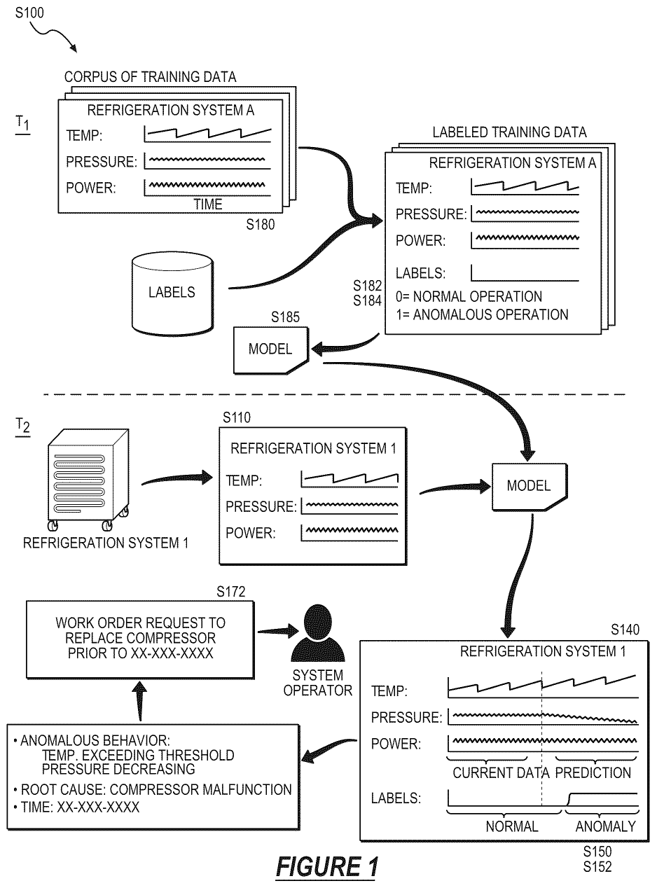

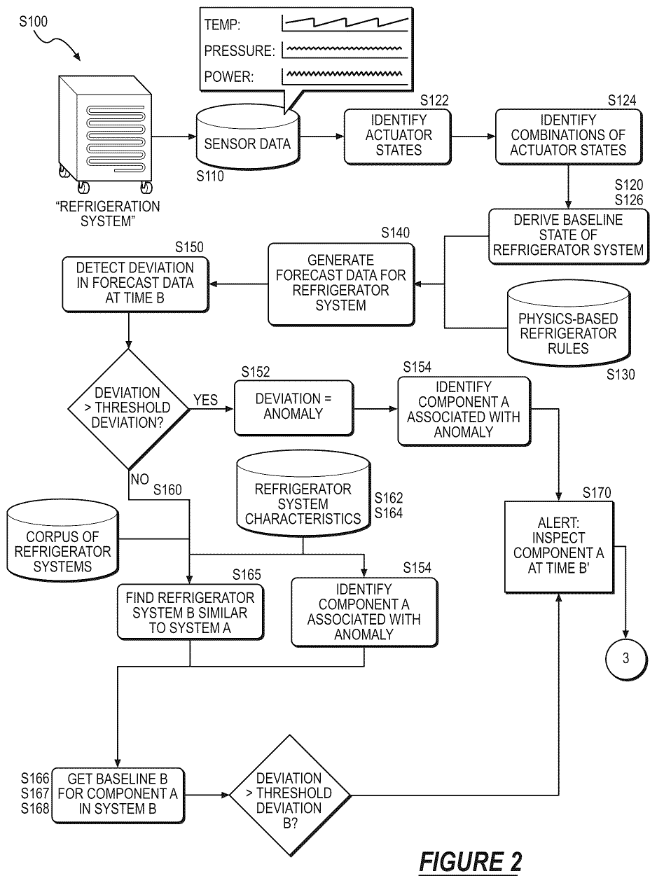

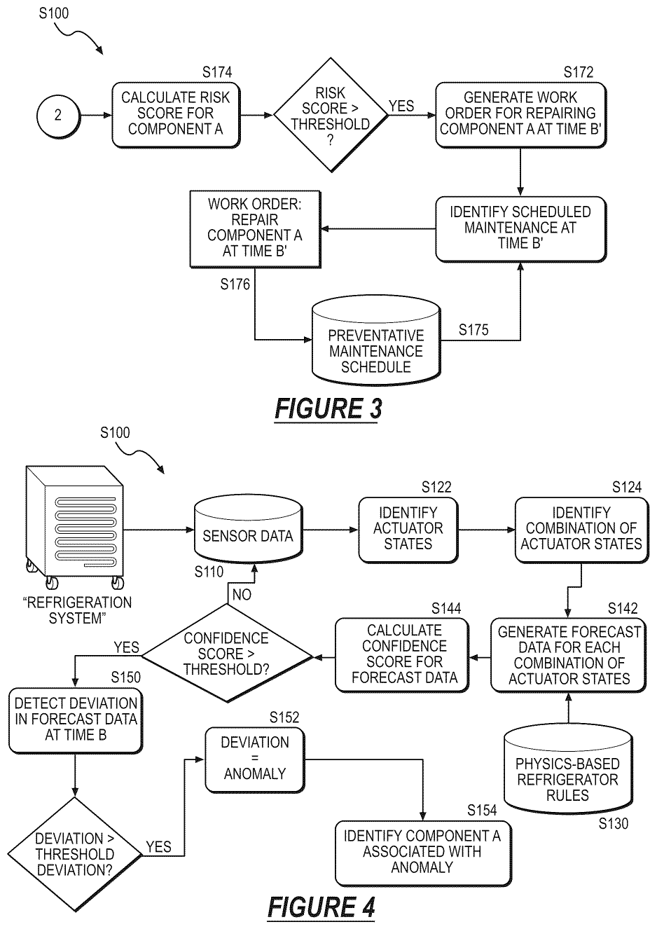

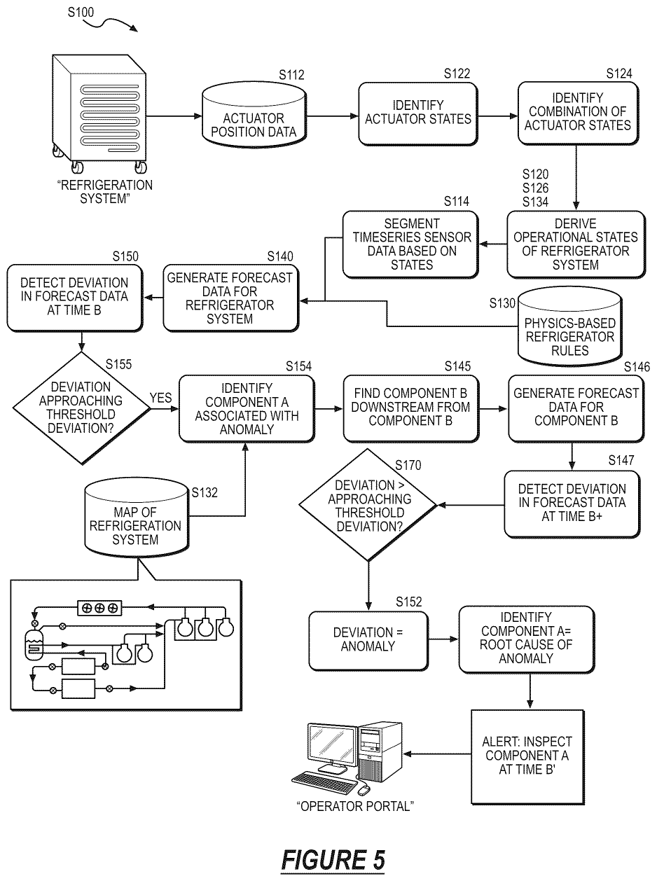

As shown in FIGS. 1-5, a method S100 includes: accessing a set of actuator position data captured during an initial time period from a set of actuators associated with a set of refrigeration components of a refrigeration system in Block S112; deriving a set of operational states of the refrigeration system based on combinations of actuator positions represented in the set of actuator position data in Block S120; accessing a first set of timeseries sensor data captured by a set of sensors, associated with the set of refrigeration components, during an initial time period in Block S110; and accessing a set of refrigeration system rules specifying nominal thermodynamic behavior of refrigeration components in Block S130.

The method S100 also includes, for each operational state in the set of operational states, generating a set of forecast sensor data representing predicted behavior of the refrigeration system in the operational state based on a segment of timeseries sensor data, representing the operational state, and the set of refrigeration system rules in Block S140.

The method S100 further includes, for a first operational state in the set of operational states: detecting a first deviation, in a first set of forecast sensor data representing predicted behavior of the refrigeration system in the first operational state, from nominal thermodynamic behavior of refrigeration components in the first operational state according to the set of refrigeration system rules in Block S150; in response to the first deviation exceeding a threshold deviation, characterizing the first deviation as a first anomaly in Block S150; accessing a graph of the refrigeration system representing thermodynamic connectivity between refrigeration components in the set of refrigeration components in Block S132; detecting a first refrigeration component, associated with the first anomaly according to the graph of the refrigeration system and the first set of forecast sensor data, as a root cause of the first anomaly in Block S154; and flagging the first refrigeration component for inspection prior to predicted onset of the first deviation according to the first set of forecast sensor data in Block S170.

### 1.1 Variation: Downstream Deviations+Known Operational States

In one variation, the method S100 includes: accessing a set of operational states of the refrigeration system based on combinations of actuator positions associated with the refrigeration system in Block S134; accessing a first set of timeseries sensor data captured by a set of sensors, associated with the refrigeration system, during an initial time period in Block S110; and, for each operational state in the set of operational states, generating a set of forecast sensor data representing predicted behavior of the refrigeration system in the operational state based on a segment of timeseries sensor data, in the first set of timeseries sensor data and representing the operational state, and a set of refrigeration system rules specifying nominal thermodynamic behavior of refrigeration components in Block S140.

This variation of the method S100 also includes, for a first operational state in the set of operational states: detecting a first deviation in a first set of forecast sensor data representing predicted behavior of the refrigeration system in the first operational state in Block S150; in response to the first deviation exceeding a threshold deviation, accessing a graph of the refrigeration system representing thermodynamic connectivity between refrigeration components in the refrigeration system in Block S132; detecting a first refrigeration component associated with the first deviation according to the graph of the refrigeration system and the first set of forecast sensor data in Block S154; detecting the first refrigeration component as a root cause of the first deviation in response to detecting propagation of deviations, analogous to the first deviation, in the first set of forecast sensor data and associated with refrigeration components thermodynamically connected to the first refrigeration component according to the graph of the refrigeration system in Block S156; and flagging the first refrigeration component for inspection prior to predicted onset of the first deviation according to the first set of forecast sensor data in Block S170.

### 1.2 Variation: Operational States+Transitional States+Segment Extraction

In another variation, the method S100 includes: accessing a set of actuator position data captured during an initial time period from actuators associated with a set of refrigeration components in Block S112; deriving a set of states of the refrigeration system based on combinations of actuator positions represented in the set of actuator position data in Block S120, the set of states including a set of operational states of the refrigeration system; and a set of transition states representing transitions between operational states; accessing a first set of timeseries sensor data captured by a set of sensors, associated with a set of refrigeration components in a refrigeration system, during an initial time period in Block S110; and accessing a set of refrigeration system rules specifying nominal thermodynamic behavior of refrigeration components during transitions between operational states in Block S130.

This variation of the method S100 also includes, for each state in the set of states: extracting a segment of timeseries sensor data from the first set of timeseries sensor data, the segment of timeseries sensor data representing the state in Block S114; and generating a set of forecast sensor data, representing predicted behavior of the refrigeration system, based on the segment of timeseries sensor data and the set of refrigeration system rules in Block S140.

This variation of the method S100 further includes: detecting a first deviation in a first set of forecast sensor data representing predicted behavior of the refrigeration system in a first transition state in the set of transition states in Block S150; in response to the first deviation exceeding a threshold deviation, accessing a graph of the refrigeration system representing connectivity between refrigeration components in the set of refrigeration components in Block S132; detecting a first refrigeration component associated with the first deviation according to the graph of the refrigeration system and the first set of forecast sensor data in Block S154; identifying the first refrigeration component as a root cause of the first deviation in Block S156; and flagging the first refrigeration component for inspection prior to predicted onset of the first deviation according to the first set of forecast sensor data in Block S170.

### 1.3 Variation: Historical Data+Timeseries Prediction Model

As shown in FIG. 1, one variation of the method S100 for preventative maintenance forecasting of refrigeration systems includes, during a first time period: accessing a corpus of historical sensor data from a set of refrigeration systems in Block S180; deriving a set of correlations between series of historical sensor data in the corpus of historical sensor data in Block S182; deriving a set of temporal patterns within the series of historical sensor data in Block S184; and compiling the set of correlations and the set of temporal patterns in a timeseries prediction model configured to forecast timeseries of future sensor data based on current sensor data in Block S185.

The method S100 further includes, during a second time period: accessing a corpus of current sensor data from a refrigeration system; executing the timeseries prediction model to generate a forecast timeseries of sensor data for a set of sensors installed in the refrigeration system based on the corpus of current sensor data; executing an anomaly detection module and a root cause analysis module to generate an anomaly prediction and a root cause prediction for the refrigeration system based on the forecast timeseries; generating a work order request for the refrigeration system based on the anomaly prediction and the root cause prediction in Block S172; populating a preventative maintenance schedule for the refrigeration system with the work order request in Block S176; and serving the preventative maintenance schedule to a user.

### 1.4 Variation: Timeseries+Anomaly+Root Cause Prediction Model

As shown in FIG. 1, one variation of the method S100 includes, during a first time period: accessing a corpus of historical sensor data from a set of refrigeration systems; accessing a set of labels for the corpus of historical sensor data; deriving a first set of correlations between series of historical sensor data in the corpus of historical sensor data; deriving a second set of correlations between the series of historical sensor data in the corpus of historical sensor data and the set of labels; detecting a set of temporal patterns within the series of historical sensor data; and compiling the first set of correlations, the second set of correlations, and the set of temporal patterns into a timeseries prediction model configured to forecast timeseries of future sensor data of the set of refrigeration systems based on current sensor data.

This variation of the method S100 further includes, during a second time period: accessing a corpus of current sensor data from a refrigeration system; executing the timeseries prediction model to generate a forecast timeseries of sensor data for a set of sensors installed in the refrigeration system, to predict a first anomaly (or “fault”) based on the forecast timeseries, and to predict the root cause of the first anomaly; generating a work order request for the refrigeration system based on the anomaly prediction and the root cause prediction; populating a preventative maintenance schedule for the refrigeration system with the work order request; and serving the preventative maintenance schedule to a user.

### 2. Applications

Generally, a computer system can execute Blocks of the method S100: to access historic sensor data output by sensors installed in a refrigeration system; to predict future behavior of the refrigeration system based on historic behavior of the refrigeration system—derived from historic sensor data output by sensors installed in the refrigeration system—and nominal behavior of refrigeration systems; to predict an instance in which a component of the refrigeration system will fail based on future behavior of the refrigeration system; to automatically detect a refrigeration component, in the refrigeration system, as a root cause (e.g., current overload, compressor failure) of the failure; and to generate a work order for preventative maintenance of the refrigeration system according to prediction of failure and identification of the refrigeration component as the root cause of the failure in the refrigeration system. The computer system can: execute this process for many or all refrigeration components in the refrigeration system; and sort or rank remediation of performance degradation (e.g., failure) of refrigeration components by their risk posed to the refrigeration system as a whole.

Therefore, the computer system can therefore automatically generate work orders for remediation of predicted failures and/or anomalous behavior of refrigeration components in a refrigeration system prior to these predicted failures and/or anomalous behavior occurring to thereby: enable a technician to proactively maintain steady (e.g., normal) operation of the refrigeration system by proactively repairing and/or replacing refrigeration components before these refrigeration components affect overall refrigeration system performance; and reduce risk of future refrigeration component failure to the overall refrigeration system to thereby reduce operational consequences of refrigeration component failures.

In particular, the computer system can: access current sensor data captured by a suite of sensors installed within a refrigeration system, this sensor data representing an operational state of the refrigeration system; access refrigeration system rules specifying nominal behavior of refrigeration components within the refrigeration system; predict future behavior of the refrigeration system according to the current sensor data—representing the operational state of the refrigeration system—and the refrigeration system rules; detect anomalous behavior and/or states of the refrigeration system in this future behavior of the refrigeration system; detect a refrigeration component (or refrigeration system operational state) as a root cause of such anomalous behavior; and populate a preventative maintenance schedule with a timeline to investigate (e.g., repair, replace) the refrigeration component. The computer system can then repeat methods and techniques as described herein for each operational state in a set of operational states for the refrigeration system.

More specifically, the computer system can: access a set of current sensor data captured by a set of sensors installed within a refrigeration system and outputting data representing statuses and/or states of refrigeration components in the refrigeration system; and generate a set of forecast sensor data based on the set of current sensor data and nominal behavior of refrigeration systems.

Therefore, by generating (e.g., predicting) future sensor data for the refrigeration system and predicting and/or detecting instances of refrigeration component performance degradation, the computer system can flag the refrigeration component for investigation prior to onset of the refrigeration component performance degradation and thereby enable the operator to preemptively repair the refrigeration component prior to the refrigeration component performance degradation, as further described below.

For example, the computer system can detect future instances of anomalous refrigeration component behavior based on this set of forecast sensor data.

In particular, the computer system can: compare forecasted behavior—according to the set of forecast sensor data—to baseline behavior, of the refrigeration component, represented by current and/or historical sensor data associated with the refrigeration component; detect deviations from baseline behavior in the set of forecast sensor data; and detect a deviation as anomalous when the deviation exceeds a threshold deviation. Then, the computer system can: detect an onset time of the deviation according to the set of forecast sensor data; and prompt an operator to repair the refrigeration component prior to the onset time of the deviation.

Accordingly, the computer system can preemptively alert an operator to preemptively repair a refrigeration component predicted to fail in the near-future, prior to such a failure to thereby reduce operational risk of the refrigeration system as a whole.

Therefore, by detecting future failure risks to the refrigeration system, the computer system can enable the operator to preemptively replace and/or repair refrigeration components causing such failures prior to the failure occurring, to thereby reduce—or eliminate—operational losses due to failure of these components (e.g., due to product loss from loss of refrigerant temperatures) and/or prevent regulation and compliance violations due to loss of refrigerant (e.g., from a leak).

Furthermore, by predicting component-level anomalies and/or failures, the computer system can enable prevention of a refrigeration system-wide failure—resulting in a larger operational burden to repair—to thereby reduce total operational consequences of maintenance for the refrigeration system.

Additionally, by detecting the components that need to be replaced and/or repairing components that cause such failures prior to the failure occurring, the computer system can enable an operator to (and/or automatically) preemptively order these components to thereby reduce a risk of supply chain disruptions impacting management of the refrigeration system (and/or a refrigeration fleet) by accounting for long(er) transit times for these refrigeration components.

### 2.1 Applications: System-Wide Monitoring and Alerting

In one variation, the computer system can implement methods and techniques as described herein to detect refrigeration system-wide anomalies based on: connections between refrigeration components in the refrigeration system; and operational states of the refrigeration system based on combinations of refrigeration component states indicated by combinations of actuator positions in the refrigeration system.

In particular, in this variation, the computer system can implement methods and techniques as described herein to: detect a set of operational states of the refrigeration system, such as based on combinations of actuator states of actuators in the refrigeration system; generate forecast sensor data for the refrigeration system based on a) the set of operational states of the refrigeration system and b) connections between the refrigeration components in the refrigeration system (e.g., based on logical refrigerant flow); detect sequential anomalies in subsets of forecast sensor data for the refrigeration system; detect a first refrigeration component as a root cause for the sequential anomalies; and flag the first refrigeration component for inspection prior to onset of the sequential anomalies as specified in the forecast sensor data.

In one implementation, the computer system can implement methods and techniques as described herein at a chat interface to enable an operator to query the computer system for upcoming predicted anomalies for each refrigeration system in a fleet of refrigeration systems. In this implementation, the computer system can receive a query from a user, the query prompting the computer system to generate a set of forecast sensor data for each refrigeration system—and/or a particular refrigeration system—in a fleet of refrigeration systems for a specified period of time, such as days or weeks into the future. The computer system can then: automatically detect future anomalies for refrigeration components in these refrigeration systems; and automatically generate and implement work orders for future repair and/or replacement of these refrigeration components responsive to the query.

Accordingly, in the foregoing implementations, the computer system can: forecast sensor data for each refrigeration component in a refrigeration system; and aggregate this forecast sensor data into a global forecast sensor data stream for the entire refrigeration system to thereby monitor the refrigeration system by monitoring each refrigeration component and/or functional states of the refrigeration system.

Furthermore, the computer system can detect a target refrigeration component as a root cause of a target anomaly according to detecting downstream anomalies analogous to (e.g., due to) the target anomaly, to thereby validate the target refrigeration component as a root cause of the anomaly and generate the work order specifying repair of the target refrigeration component.

### 2.2 Example: Prediction+Root Cause Models

In one implementation, a computer system can implement Blocks of the method S100: to execute a timeseries prediction model to forecast future timeseries of sensor data from a set of sensors installed in a refrigeration system (e.g., a commercial refrigeration system, hereinafter a “refrigeration system”)—such as days, weeks, or months in the future—based on past and current sensor data accessed from the refrigeration system; and to generate a predictive maintenance schedule and/or a work order request for the refrigeration system based on the forecast timeseries of sensor data, such as days, weeks, or months prior to real sensor data from these sensors indicating an anomaly (or “fault”), malfunction, or failure at the refrigeration system.

More specifically, the computer system—such as an edge computing device, IoT-enabled gateway, private network server, or cloud-based server—can generate the forecast timeseries of sensor data based on: past and current sensor data accessed from the refrigeration system; temporal patterns detected within the series of historical sensor data; and correlations detected between series of historical sensor data from various sensors.

The computer system can then: feed the forecast timeseries into extant (i.e., existing, previously trained or tuned) anomaly detection modules to forecast a future anomaly that may occur at the refrigeration system; and pass the forecast future anomaly into an extant anomaly detection module to predict a future root cause of this forecast future anomaly. The computer system can then generate a new work order request or update an existing work order request for the refrigeration system to preemptively address the future root cause of the forecast future anomaly before the future root cause or the forecast future anomaly leads to a system failure, yields performance degradation, or is even directly detectable at the refrigeration system.

Therefore, the computer system can leverage existing modules for anomaly detection and root cause analysis (or “diagnostics”)—configured to process current data accessed from sensors installed in the refrigeration system, detect current anomalies in the operation of the refrigeration system, and detect their respective root causes—to: detect future anomalies in the operation of the refrigeration system and predict their respective root causes given future sensor data forecast by the computer system. More specifically, the computer system can execute Blocks of the method to forecast future sensor data from a refrigeration system and to inject these forecast sensor data into extant anomaly detection and root cause analysis modules to forecast future root causes of refrigeration system degradation and/or failure without necessitating construction, retraining, or deployment of new general or refrigeration system-specific anomaly detection and root cause analysis modules.

### 2.3 System-Specific Extant Modules

Furthermore, to forecast future anomalies and/or future root causes of such anomalies for a specific refrigeration system (or a specific type or class of the refrigeration system, such as a walk-in freezer of a particular make, model, or size), the computer system can implement extant anomaly detection and/or root cause analysis modules configured to process timeseries data of the specific refrigeration system (or specific type or class of the refrigeration system). For example, to detect a future anomaly and predict a future root cause of failure at a particular walk-in freezer, the computer system can:
implement the timeseries prediction model to generate the forecast timeseries of sensor data for the particular walk-in freezer based on recent and historical sensor data collected from the particular walk-in freezer; pass these forecast timeseries of sensor data into an extant anomaly detection module configured to detect anomalies in live (i.e., real-time) sensor data from walk-in freezers; pass an output of the extant anomaly detection module into an extant root cause analysis module configured to detect root causes of live (i.e., current) anomalies at walk-in freezers; predict a future root cause of a future failure at the particular walk-in freezer; and thus coordinate preemptive, targeted repair or maintenance of this particular walk-in freezer to reduce risk or likelihood of this future failure.

The computer system can thus autonomously coordinate a preventative maintenance schedule that reflects targeted, preemptive repair and corrections of a forecast root cause of a forecast future anomaly, such as prior to performance degradation or failure of the refrigeration system. Accordingly, the computer system can efficiently allocate preventative maintenance resources to components or subsystems of a refrigeration system forecast to exhibit greatest risk of longer-term performance degradation or failure.

### 2.4 Refrigeration System Population Monitoring

Furthermore, when deployed across a population of refrigeration systems, such as within a single refrigeration or grocery facility, the computer system can: implement a generic timeseries prediction model—configured to forecast refrigeration system sensor data irrespective of the refrigeration system type—to generate a forecast timeseries of sensor data for each refrigeration system in the facility; and then inject each group of timeseries of sensor data forecast for a particular refrigeration system into system-specific anomaly detection and root cause analysis modules tailored for the type or class of the particular refrigeration system, in order to forecast anomalies and corresponding root causes at each unique refrigeration system in the facility.

Accordingly, the computer system can avoid executing a separate, unique timeseries prediction model for each type of refrigeration system present in the facility and thus limit computational resources to generate, store, load, and execute multiple system-specific timeseries prediction models for multiple types or classes of refrigeration systems in the facility.

### 2.5 Timeseries+Anomaly+Root Cause Prediction Model

In one variation, the computer system can execute a timeseries, anomaly, and root-cause prediction model to: forecast the timeseries of sensor data from the set of sensors installed in the refrigeration system; detect a future anomaly based on the forecast timeseries of sensor data; and predict the future root cause of the future anomaly. The computer system can then generate a predictive maintenance schedule and/or a work order request for the refrigeration system to address the future anomaly and/or the future root cause output by the timeseries, anomaly, and root-cause prediction model. For example, the computer system can schedule the preventative maintenance for a time preceding the occurrence of the future anomaly.

The computer system can also: access additional data—such as refrigeration system components affected by the root cause—based on the future anomaly and/or the future root cause; and specify this additional data into the work order request. For example, the computer system can specify—in the work order request—that the preventative maintenance is predicted to involve replacement of a compressor in the refrigeration system.

Therefore, the computer system can implement the timeseries, anomaly, and root-cause prediction model to: process current data accessed from sensors installed in the refrigeration system; forecast the future timeseries of sensor data from the set of sensors; detect future anomalies in the operation of the refrigeration system; and detect their respective root causes. More specifically, the computer system can execute Blocks of the method to forecast future anomalies in the operation of a refrigeration system and detect their respective root causes in the absence of general or refrigeration system-specific anomaly detection and root cause analysis modules.

### 2.6 Preventative Maintenance Coordination

Generally, the computer system can: detect the future anomaly based on the forecast timeseries of sensor data; and predict the future root cause of the future anomaly; characterize the future anomaly and/or the future root cause, such as by calculating a severity level of the future anomaly or accessing a set of refrigeration system components impacted by the future root cause; and, based on this characterization, generate a report to enable a user to allocate recourses to addressing the future anomaly. For example, the computer system can generate a report including a description of the future anomaly and the associated future root cause, a list of refrigeration system replacement components for preventative maintenance addressing the future anomaly, a type of specialist technician to perform the preventative maintenance, and predicted duration of preventative maintenance.

The computer system can also: generate a work order request—for addressing the future anomaly and/or the associated future root cause—scheduled for a time preceding the predicted occurrence of the future anomaly; populate the work order request with the report; and serve the work order request to the user, such as an operator of the refrigeration system or a maintenance technician for the refrigeration system.

Accordingly, the computer system can leverage the forecast timeseries to predict a future deviation from normal operation of the refrigeration system, predict a root case of this future deviation, and automatically schedule preventative maintenance for the refrigeration system: to prevent the deviation, such as by remedying the root cause of the deviation, and thus reduce likelihood of future failure or performance degradation of the refrigeration system via the forecast deviation or predicted root cause.

Thus, the computer system can prevent failures of the refrigeration system. Furthermore, by providing the report on the first anomaly to the system operator and/or the maintenance technician, the computer system can enable the maintenance technician to avoid diagnosing the root cause of the anomaly in the refrigeration system, thereby reducing service time. Furthermore, by scheduling the preventative maintenance (only) for a time preceding the first anomaly, the computer system can avoid scheduling preventative maintenance when it is not needed.

The computer system can also estimate the operational consequences of a refrigeration system failure if the root cause of the future anomaly is not addressed. For example, the computer system can predict that the future anomaly is a precursor to a compressor failure and assess the potential effects on the refrigeration system performance, reliability, and/or availability. Based on this assessment, the computer system can prioritize scheduling the work order request to address the future anomaly. For instance, the computer system can prioritize addressing the future anomaly if the consequences of not addressing it, such as extended downtime or reduced system reliability, are anticipated to be more significant than the resources associated with the work order (e.g., component replacement, man-hours, temporary loss of service).

Furthermore, the computer system can prioritize addressing future anomalies based on a set of logistical and operational factors, such as technician availability, holiday schedules, replacement component availability, and existing work orders at associated (e.g., sister) facilities.

Additionally, or alternatively, the computer system can prioritize scheduling the work order request to address a future anomaly, among several predicted future anomalies, associated with the highest operational impact on the refrigeration system. For example, the computer system can prioritize addressing a first future anomaly indicating a system failure (e.g., complete breakdown) over a second future anomaly indicating a slight degradation in performance of the refrigeration system. Accordingly, the computer system can autonomously allocate resources to addressing anomalies associated with most impactful operational consequences.

Therefore, the computer system can: guide an operator toward avoiding repairs for more substantive or catastrophic failures at a refrigeration system; guide the operator in prioritizing preventative maintenance tasks across a fleet of refrigeration systems; and support the operator in efficiently allocating resources, reducing human intervention, and improving efficiency of maintenance of the fleet of refrigeration systems.

The method S100 is described as a method for predicting future timeseries of sensor data—and detecting future anomalies—based on past and current data from a set of sensors installed in the refrigeration system. However, the method S100 can also be executed to predict future timeseries of sensor data—and detecting future anomalies—based on data generated by “virtual sensors” configured to derive systems characteristics in systems lacking certain sensors, as described in U.S. patent application Ser. No. 18/426,270, which is incorporated herein by reference. Additionally or alternatively, the computer system can access timeseries sensor data captured by additional sensors installed within the refrigeration system to execute Blocks of the method S100, such as when virtual sensor data is unavailable and/or unreliable.

In addition, the method S100 is described as a method for preventative maintenance forecasting of refrigeration systems. However, the method S100 can also be executed to predict future anomalies and schedule preventative maintenance—based on forecast timeseries of sensor data—in other types of systems, such as heating, ventilation, and air conditioning (HVAC) systems, industrial machinery, and power generation systems.

### 3. Sensors and Refrigeration System Networking

In one implementation, the computer system described herein is configured to forecast performance of large-scale refrigeration systems, such as those deployed in supermarkets. A refrigeration system can include: a refrigerant receiver; a compressor; a condenser; an expansion device; an evaporator; and a refrigerated volume. The refrigerant receiver stores a volume of refrigerant for use throughout the refrigeration system. The compressor can increase pressure within the refrigeration system, such as to raise the temperature of the refrigerant. The condenser enables hot refrigerant to cool and exchange heat with the ambient environment, thereby cooling the refrigerated volume and changing the refrigerant to a liquid. The expansion device reduces the pressure of liquid refrigerant, which changes to a very cold liquid/vapor mix. The evaporator turns liquid refrigerant back into a vapor by increasing temperature and pressure of the refrigerant.

Generally, a refrigeration system can include a set of sensors: installed or embedded in the refrigeration unit; and configured to output sensor data indicative of performance of the refrigeration unit. In one implementation, the computer system (e.g., local controller of the refrigeration unit) interfaces with the refrigeration system and/or with a separate sensor module arranged on or in the refrigeration system to collect sensor data representing statuses and operating characteristics of the refrigeration system over time.

In one example, the refrigeration system can include integrated sensors: configured to stream a sequence of readings to the local controller of the refrigeration unit. In another example, the refrigeration system can include a discrete sensor module: including a set of sensors installed in the refrigeration unit; and configured to periodically receive sensor data from the set of sensors. In one implementation, the local controller of the refrigeration unit or the sensor module can include a wired or wireless communication channel with a gateway, which passes sensor data to the computer system (e.g., remote computer system).

For example, the integrated sensors and/or the sensor module can include sensors such as: a temperature sensor configured to output readings representing temperature of the components of the refrigeration unit; a pressure sensor configured to output readings representing pressure inside sections of the refrigeration unit; a vibration sensor configured to output readings representing vibration level of the components of the refrigeration unit; a noise sensor configured to output readings representing a noise level of the refrigeration unit; and a power meter configured to output readings representing the power consumption of the components of the refrigeration unit.

In another example, a local controller within the refrigeration system and/or an independent module in communication with the set of sensors and/or other refrigeration systems (or other refrigeration components within the refrigeration system) can execute Blocks of the method S100.

### 3.1 Operational States

Generally, the computer system can derive operational states of the refrigeration system, such as discrete, temporally persistent state of the refrigeration system representing a thermodynamically steady state.

In particular, the computer system can: access a set of actuator position data captured during an initial time period from a set of actuators associated with a set of refrigeration components of a refrigeration system; detect recurring combinations of actuator positions while the refrigeration system is operating in a steady-state; and derive a set of operational states of the refrigeration system based on these combinations of actuator positions represented in the set of actuator position data.

In one implementation, the computer system can derive the set of operational states of the refrigeration system based on detecting combinations of actuator positions representing steady operating states of the refrigeration system based on temporal persistence of combinations of actuator positions. For example, the computer system can: detect a first combination of actuator positions in the set of actuator position data; detect a first duration of an instance of the first combination of actuator positions; and, in response to the first duration exceeding a threshold duration (e.g., five minutes), identify the first combination of actuator positions as an operational state.

Similarly, the computer system can detect transitional states, of the refrigeration system, representing transition periods between operational states. For example, the computer system can: detect a second combination of actuator positions in the set of actuator position data; detect a second duration of an instance of the second combination of actuator positions; and, in response to the second duration falling below the threshold duration (e.g., thirty seconds), identify the second combination of actuator positions as a transitional state. In particular, the computer system can detect a first transition period between the first operational states and a second operational states based on a second combination of actuator positions representing a combination of the first operational state and the second operational state.

Additionally or alternatively, the computer system can: detect combinations of actuator positions representing a set of operational state transitions between operating states of the refrigeration system; and predict a duration of each operational state in the set of operational states based on the first set of timeseries sensor data.

In one implementation, the computer system can segment a first set of timeseries sensor data, captured for a first refrigeration system, into segments of timeseries sensor data representing distinct operational states of the refrigeration system. For example, the computer system can: detect a first combination of actuator positions, in the set of actuator position data, representing the first operational state; isolate a first segment of timeseries sensor data representing the first combination of actuator positions; detect a second combination of actuator positions, in the set of actuator position data and distinct from the first combination of actuator positions, representing a second operational state; isolate a second segment of timeseries sensor data representing the second combination of actuator positions; detect a third combination of actuator positions in the set of actuator position data representing a transition state from the first operational state to the second operational state; and isolate a third segment of timeseries sensor data representing the third combination of actuator positions.

Additionally or alternatively, the computer system can define a set of environmental states based on virtual sensor data. In particular, the computer system can define a set of states including a time of day, an occupied/unoccupied state of a store, and/or other environmental states associated with the refrigeration system. In this variation, the computer system can define the set of operational states based on a combination of environmental states and/or other sensor/actuator /ta/ For example, the computer system can define an operational state based on: a distribution of sensor readings; continuous controller output signals; discrete controller output signals; refrigeration component (health) status; refrigeration system (health) status; environmental states; and/or any other refrigeration system metric.

Therefore, the computer system can derive baseline operational states of the refrigeration system to derive a baseline functionality of the refrigeration system, to thereby later detect deviations from this baseline operational state as further described herein.

### 4. Single-Sensor Monitoring

Generally, the computer system can implement methods and techniques as described herein for a first sensor, in the set of sensors, to: access timeseries sensor data captured by the first sensor; associate the timeseries sensor data captured by the first sensor with a first refrigeration component in a refrigeration system; detect states (e.g., baseline state, anomalous state, operational states, transition states) of the refrigeration component according to the timeseries sensor data; predict future sensor data based on captured timeseries sensor data and nominal refrigeration component behavior; detect a future anomalous state—based on a deviation in the future sensor data—of the refrigeration component; and flag this refrigeration component for investigation (e.g., repair, replacement) prior to onset of the future anomalous state.

In one example, the computer system can: access a first set of timeseries sensor data captured by the first sensor associated with a compressor; access a set of refrigeration system rules specifying nominal compressor behavior, such as a nominal range of compressor motor voltage; generate a first set of forecast sensor data including forecasted motor current values for the compressor; detect a first motor current value in the first set of forecast sensor data, the first motor current value exceeding the nominal range of compressor motor current; characterize the first motor current value as an anomaly in response to the first motor current value exceeding a threshold motor current value defined by the operational state; and flag the compressor for inspection prior to predicted onset of the first anomaly.

Therefore, by accessing local sensor data, forecasting future data based on this local sensor data, and comparing this future data to an operational state of a refrigeration component, the computer system can preemptively detect predicted instances of decline in performance (e.g., the anomaly) for the refrigeration component and alert an operator of a time period for onset of the decline in performance to thereby enable the operator to dispatch a technician to investigate the refrigeration component and decrease risk posed to the refrigeration system by this refrigeration component.

### 4.1 Data Access+Association

Generally, the computer system can: access a first set of timeseries sensor data captured by a first sensor associated with a first refrigeration component in a refrigeration system; associate the first set of timeseries sensor data with an operational state of the first refrigeration component; and access a set of refrigeration system rules specifying nominal behavior of refrigeration components.

In particular, the computer system can remotely sync to an on-site sensor (e.g., temperature sensor, actuator sensor, transducer, mass flow sensor, pressure sensor, voltage sensor). The computer system can then query the on-site sensor for historical data generated during a target time period (e.g., the past week, the past month, the past year, current sensor data).

In one implementation, the computer system can access a set of historical sensor data including: sensor labels; alphanumeric strings representing refrigeration components (e.g., in ASHRAE 223, Brick ontology); controller identifiers; operator comments and/or tags (e.g., in Project Haystack form); and/or other metadata related to the refrigeration system components and statuses of these components. The computer system can then associate the set of historical sensor data with a refrigeration component in the set of refrigeration components within a refrigeration system, such as based on a sensor data type and/or identification of the refrigeration component associated with the sensor.

In one example, the computer system can access the set of refrigeration system rules (e.g., physics-based rules) specifying: a logical flow of the refrigeration system; and nominal ranges of sensor data associated with particular refrigeration components of a refrigeration component type (e.g., compressor, evaporator, condenser).

The computer system can then implement the set of refrigeration system rules for deriving predicted refrigeration component behavior as further described below.

### 4.2 Operational State Detection

Generally, the computer system can detect an operational state of the refrigeration component based on historical sensor data associated with the refrigeration component. In particular, the computer system can: access historical sensor data captured by the first sensor associated with the first refrigeration component; detect temporal patterns in the historical sensor data; and compile these temporal patterns into an operational state of the first refrigeration component.

In one implementation, the computer system can detect an operational state of the refrigeration component based on actuator states, sensed by the first sensor, of an actuator associated with the refrigeration component. For example, the computer system can detect a first state of a first actuator associated with the first sensor based on the first set of timeseries sensor data in Block S122; and associate the first state of the first actuator with the operational state of the first refrigeration component in Block S124. Additionally, in this example, the computer system can: access a second set of timeseries sensor data captured by the first sensor associated with the first refrigeration component; detect a second state of the first actuator associated with the first sensor based on the second set of timeseries sensor data in Block S122; and associate the second set of timeseries sensor data with the operational state of the first refrigeration component in Block S124. Accordingly, in the foregoing example, the computer system can detect states of the refrigeration component as an operational state of the refrigeration component—the operational state representing sensor data captured during normal operational activity of the refrigeration component.

Similarly, the computer system can detect state changes (e.g., between a first state and a second state) based on actuator states, captured by the first sensor, of an actuator associated with the refrigeration component.

For example, the computer system can: detect a state change of the refrigeration component, as the first actuator transitions between the first state and the second state, in the first set of timeseries sensor data; and associate the state change with the operational state of the first refrigeration component.

Additionally or alternatively, the computer system can: detect a state change of the refrigeration component as the first actuator transitions between the first state and the second state; detect a subset of timeseries sensor data, in the set of timeseries sensor data, representing the state change; and associate the subset of timeseries sensor data with the state change of the first refrigeration component. Then, the computer system can associate the subset of timeseries sensor data and the state change with the operational state of the first refrigeration component.

Therefore, by deriving an operational state of the refrigeration component—such as during an initial and/or setup time period—the computer system can detect nominal behavior of the refrigeration component to thereby enable identification of anomalous activity deviating from this nominal behavior as further described herein.

### 4.3 Future Sensor Data Prediction+Generation

Generally, the computer system can generate a first set of forecast sensor data based on the first set of timeseries sensor data and the set of refrigeration system rules. In particular, the computer system can generate forecast sensor data for a refrigeration component in the refrigeration system based on historical sensor data associated with the refrigeration component and/or refrigeration system rules specifying nominal behavior of refrigeration components.

In one implementation, the computer system can generate a set of forecast sensor data for each state in a set of states (e.g., active, inactive, open, closed) defining an operational state for the refrigeration component. In particular, the computer system can: detect a set of states of the refrigeration component based on state changes of the refrigeration component represented in the first set of timeseries sensor data; and, for each state in the set of states, generate a subset of forecast sensor data and aggregate the subset of forecast sensor data into the first set of forecast sensor data.

In one example, the computer system can: generate a first subset of forecast sensor data based on the first subset of timeseries sensor data representing the first state of the refrigeration component; generate a second subset of forecast sensor data based on the second subset of timeseries sensor data representing the second state of the refrigeration component; generate a third subset of forecast sensor data based on the third set of timeseries sensor data representing the state change of the refrigeration component; and compile the first subset of forecast sensor data, the second subset of forecast sensor data, and the third subset of forecast sensor data into the first set of forecast sensor data.

Accordingly, in this example, the computer system can generate forecast sensor data according to states and/or state changes of the refrigeration component.

In one variation, the computer system can generate the set of forecast sensor data based on: the set of timeseries sensor data; the set of refrigeration system rules specifying nominal behavior of refrigeration components; and ambient humidity, weather forecasts, temperature, and/or other ambient conditions proximal the refrigeration system.

In another implementation, the computer system can: detect patterns of activity in the first set of timeseries sensor data; and project these patterns forward to generate a first set of forecast sensor data. Additionally or alternatively, the computer system can implement regression techniques and/or machine learning to generate the first set of forecast sensor data. In particular, the computer system can access a timeseries prediction model configured to forecast timeseries of future sensor data based on past and current sensor data. In one example, the computer system can then: derive a correlation between increasing temperature values—in a series of temperature readings—from a sensor within a refrigeration volume and decreasing pressure values—in a series of pressure readings—from a sensor associated with (e.g., downstream of) a compressor, which indicates a possible compressor failure.

In one example of the foregoing implementation, the computer system can: access a corpus of historical sensor data from a set of refrigeration systems; derive a set of correlations between sets of historical sensor data in the corpus of historical sensor data; derive a set of temporal patterns within sets of historical sensor data; and compile the set of correlations and the set of temporal patterns in a timeseries prediction model (e.g., based on a foundational timeseries prediction model such as TimeGPT and/or TimesFM) configured to forecast timeseries of future sensor data based on current sensor data. In this example, the computer system can generate the first set of forecast sensor data based on the timeseries prediction model.

Therefore, by leveraging historical patterns and/or correlations between sensor data associated with the refrigeration component to forecast future sensor data for the refrigeration component, the computer system can forecast future behavior and/or activity of the refrigeration component to thereby detect instances of deviation from nominal behavior and/or activity as further described below.

### 4.4 Single-Sensor: Deviation Detection+Anomaly Characterization

Generally, the computer system can detect a deviation from the operational state for the refrigeration component. In particular, the computer system can: generate a set of forecast sensor data for the refrigeration component as described herein; detect a deviation, from the operational state, in the set of forecast sensor data; and predict onset of refrigeration component degradation based on detection of the deviation.

In one implementation, the computer system can generate a predicted behavior curve, based on the set of refrigeration system rules, representing expected behavior of the refrigeration component in the first operational state. Additionally or alternatively, the computer system can access a predicted behavior curve, from the set of refrigeration system rules, representing expected behavior of the refrigeration component in the first operational state. The computer system can then detect the deviation in response to detecting a deviation, in the first set of forecast sensor data, from the predicted behavior curve, the deviation exceeding the threshold deviation.

In one implementation, the computer system can: generate a first subset of forecast sensor data associated with a first operational state in a set of operational states of the first refrigeration component; generate a second subset of forecast sensor data associated with a second operational state in the set of operational states of the first refrigeration component; generate a third subset of forecast sensor data associated with a transition state (e.g., a state change) in the set of operational states of the first refrigeration component; and detect the first deviation in the first subset of forecast sensor data associated with the first operational state in the set of operational states. In particular, in this variation, the computer system can detect the first deviation in the first subset of forecast sensor data, the deviation distinct from the second state and the third state of the first refrigeration component. Accordingly, the computer system can associate the deviation with the first state of the refrigeration component.

In one variation, the computer system can: detect a trend of forecast sensor data, in a first set of forecast sensor data, approaching a deviation, the trend falling below the threshold deviation in Block S155; and generate a second set of forecast sensor data in Block S140. For example, the computer system can: access a set of timeseries sensor data captured by a sensor associated with a refrigeration component in the refrigeration system; derive an operational state of the refrigeration component based on the set of timeseries sensor data; and generate a set of forecast sensor data based on the set of timeseries sensor data and the set of refrigeration system rules. In this example, in response to detecting the set of forecast sensor data approaching a threshold deviation from the operational state, the computer system can: generate a second set of forecast sensor data based on the set of timeseries sensor data, the set of refrigeration system rules, and the second set of forecast sensor data; and detect a second deviation, from the operational state, in the second set of forecast sensor data.

In response to the second deviation exceeding the threshold deviation, the computer system can: characterize the second deviation as an anomaly; associate the anomaly with the refrigeration component; and flag the refrigeration component for inspection prior to a predicted onset of the second anomaly according to the second set of forecast sensor data.

Additionally or alternatively, during the first time period, the computer system can calculate a first confidence score for the first set of forecast sensor data in Block S144. In response to the first confidence score falling below a threshold confidence score, during a second time period the computer system can: access a second set of timeseries sensor data associated with the first refrigeration component; generate a second set of forecast sensor data based on the set of timeseries sensor data, the set of refrigeration system rules, and the second set of forecast sensor data; and detect a deviation, from the operational state, in the second set of forecast sensor data. In response to the deviation exceeding the threshold deviation, the computer system can: characterize the deviation as an anomaly; associate the anomaly with the refrigeration component; and flag the refrigeration component for inspection prior to a predicted onset of the second anomaly according to the second set of forecast sensor data.

Additionally or alternatively, in response to detecting the set of forecast sensor data approaching a threshold deviation from the operational state, the computer system can flag the refrigeration component for inspection prior to a predicted onset of an anomaly according to the set of forecast sensor data. In this example, the computer system can predict that an anomaly will occur based on a trend of the forecast sensor data, and thereby flag the refrigeration component for inspection prior to predicted onset of the anomaly according to the trend of the forecast sensor data.

Therefore, in the foregoing implementations, the computer system can detect deviations—such as from the operational state of the refrigeration component—in forecast sensor data to thereby detect instances of future anomalous behavior of the refrigeration component.

### 4.5 Anomaly Validation

Generally, the computer system can validate detection of the deviation as an anomaly and/or correct an operational state for the refrigeration component. In particular, the computer system can calculate a confidence score for the forecast sensor data in Block S144; and, in response to the confidence score exceeding a threshold confidence score and in response to the deviation exceeding a threshold deviation, characterize the deviation as an anomaly in Block S152.

In one implementation, the computer system can calculate a confidence score for the first set of forecast sensor data based on resolution of the timeseries sensor data captured by the sensor. In this implementation, the computer system can: generate the first set of forecast sensor data based on the first set of timeseries sensor data; and calculate a confidence score for the first set of forecast sensor data proportional to a resolution of the first set of timeseries sensor data.

Additionally or alternatively, the computer system can calculate a confidence score for the first set of forecast sensor data based on a length of time of the timeseries sensor data. For example, the computer system can: generate the first set of forecast sensor data based on the first set of timeseries sensor data, a length of the first set of forecast sensor data falling below a length of the first set of timeseries sensor data; and calculate a confidence score for the first set of forecast sensor data based on the length of the first set of forecast sensor data, the first confidence score exceeding a threshold confidence score.

In one example, the computer system can: calculate a first confidence score for the first set of forecast sensor data based on resolution of the first set of timeseries sensor data. In response to the first confidence score falling below a threshold confidence score, the computer system can: access a second set of timeseries sensor data captured by the first sensor associated with the first refrigeration component; detect a state change from the operational state to a second state of the first refrigeration component based on the second set of timeseries sensor data; detect correspondence between the deviation and the state change; characterize the deviation as the state change; and withhold flagging the refrigeration component for inspection.

Additionally or alternatively, the computer system can calculate a first confidence score for the first set of forecast sensor data based on resolution of the first set of timeseries sensor data. In response to the first confidence score falling below a threshold confidence score, the computer system can: access a second set of timeseries sensor data captured by a second sensor associated with a second refrigeration component functionally dependent on the first refrigeration component in Block S145; generate a second set of forecast sensor data based on the second set of timeseries sensor data and the set of refrigeration system rules in Block S146; detect a second deviation, correlated with the first deviation, in the second set of forecast sensor data, the second deviation occurring temporally sequential to the first deviation in Block S147; calculate a second confidence score for the first set of forecast sensor data based on the second deviation occurring temporally sequential to the first deviation; and flag the first refrigeration component for inspection in response to the second confidence score exceeding the threshold confidence score.

Similarly, in one variation, the computer system can validate detection of the anomaly based on anomaly detection in forecast sensor data for refrigeration components functionally connected to the first refrigeration component. For example, the computer system can: access a second set of timeseries sensor data captured by a set of sensors associated with a set of refrigeration components in the refrigeration system; detect a subset of refrigeration components, in the set of refrigeration components, functionally connected to the first refrigeration component, based on the second set of timeseries sensor data and the set of refrigeration system rules; generate a second set of forecast sensor data, based on the second set of timeseries sensor data and the set of refrigeration system rules, for the subset of refrigeration components; scan the second set of forecast sensor data for deviations analogous to the first deviation; detect a second deviation in the second set of forecast sensor data analogous to the first deviation; and flag the first refrigeration component for inspection in response to the second deviation exceeding the threshold deviation.

For example, the computer system can: detect a subset of refrigeration components, in the set of refrigeration components, functionally connected downstream of the first refrigeration component, based on the second set of timeseries sensor data and the set of refrigeration system rules, the subset of refrigeration components including a compressor downstream of the first refrigeration component (e.g., a condenser fan) along a refrigerant flow path; generate a second set of forecast sensor data, based on the second set of timeseries sensor data and the set of refrigeration system rules, for the subset of refrigeration components, the second set of forecast sensor data including forecasted compressor discharge temperature values; scan the second set of forecast sensor data for deviations analogous to the first deviation, such as forecasted compressor discharge temperature values indicative of compressor overheating resulting from degraded condenser fan performance; detect a second deviation in the second set of forecast sensor data analogous to the first deviation, the second deviation including a forecasted increase in compressor discharge temperature above a nominal discharge temperature range; and flag the first refrigeration component for inspection in response to the second deviation exceeding the threshold deviation, the second deviation indicating that the first refrigeration component is projected to cause downstream performance degradation in the compressor.

Accordingly, in the foregoing examples, in response to the confidence score falling below a threshold confidence score, the computer system can validate detection of the deviation as an anomaly based on detecting an analogous deviation in a second refrigeration component functionally connected (e.g., downstream, upstream) to the refrigeration component.

In one variation, the computer system can characterize the deviation as an anomaly in response to detecting deviation from nominal behavior of refrigeration components similar to the first refrigeration component, such as refrigeration components of the same refrigeration component type as the first refrigeration component, and/or refrigeration systems similar to the refrigeration system of the first refrigeration component.

For example, the computer system can: access a second set of timeseries sensor data captured by a second sensor associated with a second refrigeration component in the refrigeration system; associate the second set of timeseries sensor data with a second operational state of the second refrigeration component; generate a second set of forecast sensor data based on the second set of timeseries sensor data and the set of refrigeration system rules; and detect a second deviation, from the second operational state, in the second set of forecast sensor data. In response to detecting the second deviation falling below a second threshold deviation in Block S160, the computer system can then: detect a first refrigeration component type of the second refrigeration component in Block S162; access a first set of refrigeration system characteristics associated with the refrigeration system in Block S164; detect a second refrigeration system, in a corpus of refrigeration systems, characterized by a second set of refrigeration system characteristics approximating the first set of refrigeration system characteristics in Block S165; detect a third refrigeration component, of the first refrigeration component type, in the second refrigeration system in Block S166; access a third operational state of the third refrigeration component in Block S167; associate the third operational state with the second operational state of the second refrigeration component in Block S178; detect a third deviation, from the third operational state, in the second set of forecast sensor data; in response to the third deviation exceeding the second threshold deviation, characterize the third deviation as a second anomaly associated with the second refrigeration component; and flag the second refrigeration component for inspection prior to predicted onset of the second anomaly according to the second set of forecast sensor data.

Therefore, by validating characterization of the deviation as an anomaly based on characteristics of the refrigeration system and/or the refrigeration component, the computer system can increase confidence for flagging the refrigeration component for inspection and/or converge on a predicted onset of the anomaly.

### 5. Multi-Sensor Monitoring

Generally, the computer system can repeat methods and techniques as described herein for a set of sensors in a refrigeration system. In particular, the computer system can: access a set of timeseries sensor data captured by a set of sensors deployed in a refrigeration system; detect a set of operational states of the refrigeration system represented in the set of timeseries sensor data; predict future sensor data based on captured timeseries sensor data and nominal refrigeration system behavior (or activity) for each operational state; detect a future anomalous state—based on a deviation in the future sensor data—of the refrigeration component; and flag this refrigeration component for investigation (e.g., repair, replacement) prior to onset of the future anomalous state.

Accordingly, the computer system can: access a corpus of historical sensor data associated with a refrigeration system, the corpus of historical sensor data captured by sensors deployed within the refrigeration system and connected to refrigeration components in a set of refrigeration components; derive (and/or otherwise access) connections between refrigeration components in the refrigeration system based on logical, physics-based refrigeration cycle flows; derive a set of operational states of the refrigeration system based on the corpus of historical sensor data and connections between refrigeration components in the refrigeration system; forecast future sensor data for the refrigeration system; detect a deviation from the operational states in the forecast sensor data; and flag refrigeration components associated with the deviation for investigation, prior to predicted onset of the deviation, in response to the deviation exceeding a threshold deviation.

### 5.1 Accessing Historical Data and Label Generation

Generally, the computer system can: access a first set of timeseries sensor data captured by a set of sensors associated with a refrigeration system; and associate the first set of timeseries sensor data with an operational state of the refrigeration system.

In particular, the computer system can remotely sync to a set of on-site sensors (e.g., temperature sensors, actuator sensors, transducers, mass flow sensors, pressure sensors, voltage sensors). The computer system can then query the set of on-site sensors for historical data generated during a target time period (e.g., the past week, the past month, the past year, current sensor data).

In one implementation, the computer system can access a set of historical sensor data including: sensor labels; alphanumeric strings representing refrigeration components; controller identifiers; operator comments and/or tags; and/or other metadata related to the refrigeration system components and statuses of these components. The computer system can then associate the set of historical sensor data with a refrigeration component in the set of refrigeration components within a refrigeration system, such as based on a sensor data type and/or identification of the refrigeration component associated with the sensor.

In one example, the computer system can access the set of refrigeration system rules (e.g., physics-based rules) specifying: a logical flow of the refrigeration system; and nominal ranges of sensor data associated with particular refrigeration components of a refrigeration component type (e.g., compressor, evaporator, condenser).

In one implementation, the computer system can access a corpus of historical sensor data generated by a population of refrigeration systems. For example, the corpus of historical sensor data can include timeseries of concurrent sensor data, such as refrigeration volume temperature, power consumption, compressor status, refrigeration system door opening/closing events, ambient temperature, ambient humidity, and any other relevant data (e.g., defrost cycles, compressor pressure levels).

In one implementation, the computer system can normalize the corpus of historical sensor data. In one example, the computer system can execute interpolation, forward filling, or imputation techniques to replace missing data with imputed/interpolated values and ensure that each data stream in the corpus of historical sensor data is sampled at a single sampling rate.

In one implementation, the computer system can access a set of labels for the corpus of historical sensor data, the set of labels indicating: known anomalies; known system failures; known failures of specific components; known work order requests; and/or any other relevant information. More specifically, the computer system can: access a first series of temperature readings, in the corpus of historical sensor data; and access a first series of labels, in the set of labels, synchronized to the first series of temperature readings, the first series of labels indicating an anomalous temperature value and a compressor failure occurring at a first timestamp.

Additionally, or alternatively, the computer system can access a set of historical maintenance data including records of past work orders associated with the timeseries of sensor data in the corpus of historical sensor data; and transform the historical maintenance data into the set of labels for the corpus of historical sensor data. For example, the set of historical maintenance data can include date and time, type of maintenance (e.g., preventative, corrective, emergency), refrigeration system components involved in the maintenance (e.g., compressor, fan, sensors), problem description (e.g., temperature fluctuation, compressor failure), and problem resolution actions taken during maintenance (e.g., component replacement, recalibration, maintenance duration, maintenance frequency). The computer system can then transform the historical maintenance data into the set of labels by: detect a segment of a timeseries of sensor data that is temporally aligned with a maintenance event in the set of historical maintenance data; and generating a series of labels for the maintenance event, temporally aligned with the segment.

### 5.2 Operational State Detection

Generally, the computer system can detect an operational state of the refrigeration system based on historical sensor data associated with the refrigeration system. In particular, the computer system can: access historical sensor data captured by the set of sensors associated with the refrigeration system; detect temporal patterns in the historical sensor data; and compile these temporal patterns into an operational state of the refrigeration system.

In one implementation, the computer system can derive an operational state of the refrigeration system—including a set of refrigeration components—based on patterns of actuators detected in the first set of timeseries sensor data associated with the set of sensors.

For example, for each refrigeration component in the set of refrigeration components, the computer system can: detect a first state of a first actuator, associated with the first sensor, based on the first set of timeseries sensor data; detect a first subset of timeseries sensor data, in the set of timeseries sensor data, representing the first position of the first actuator; detect a second position of the first actuator, associated with the first sensor, based on the first set of timeseries sensor data; detect a second subset of timeseries sensor data, in the set of timeseries sensor data, representing the second position of the first actuator; detect a transitional state of the refrigeration component as the first actuator transitions between the first position and the second position; and detect a third subset of timeseries sensor data, in the set of timeseries sensor data, representing the transitional state of the refrigeration component.

Additionally or alternatively, for each refrigeration component in the set of refrigeration components, the computer system can: detect a set of timeseries sensor data captured by a sensor, in the set of sensors, connected to the refrigeration component; and detect a set of transitional states of the refrigeration component based on state changes of the refrigeration component represented in the set of timeseries sensor data.

Accordingly, the computer system can detect states of a set of actuators, and/or state changes of the set of actuators, for each refrigeration component in the refrigeration system, and derive the operational state of the refrigeration system based on nominal behavior of these actuators according to states and state changes of the set of actuators.

Therefore, by deriving an operational state of the refrigeration system—such as during an initial and/or setup time period—the computer system can detect nominal behavior of the refrigeration system to thereby enable identification of anomalous activity deviating from this nominal behavior as further described herein.

### 5.3 Future Sensor Data Prediction+Generation

Generally, the computer system can generate a set of forecast sensor data, for the refrigeration system, based on the set of timeseries sensor data and the set of refrigeration system rules. In particular, the computer system can generate forecast sensor data for a refrigeration system based on historical sensor data associated with the refrigeration system and/or refrigeration system rules specifying nominal behavior of refrigeration components in the refrigeration system.

In one implementation, the computer system can generate a set of forecast sensor data for each operational state in the set of operational states of the refrigeration system. For example, for each refrigeration component in the set of refrigeration components, the computer system can: generate a first subset of forecast sensor data based on the first set of timeseries sensor data representing a first state of the refrigeration component; generate a second subset of forecast sensor data based on the second set of timeseries sensor data representing a second state of the refrigeration component; and generate a third subset of forecast sensor data based on the third set of timeseries sensor data representing a third state (e.g., a state change between the first state and the second state) of the refrigeration component. The computer system can then compile the first subset of forecast sensor data, the second subset of forecast sensor data, and the third subset of forecast sensor data into the first set of forecast sensor data.

In another implementation, the computer system can generate forecast sensor data based on scheduled maintenance visits. For example, the computer system can: access a maintenance schedule defining a first scheduled maintenance visit at a first future time and a second scheduled maintenance visit at a second future time; and, for each operational state in the set of operational states, generate the set of forecast sensor data representing predicted behavior of the refrigeration system in the operational state from a current time to the second future time corresponding to the second scheduled maintenance visit. Therefore, the computer system can derive predicted behavior of the refrigeration system prior to a next scheduled maintenance visit to thereby enable the computer system to automatically schedule timely preventative maintenance as further described below.

Additionally or alternatively, for each refrigeration component in the set of refrigeration components, the computer system can: detect a set of operational states of the refrigeration component; for each operational state in the set of operational states, generate a set of forecast sensor data; and aggregate the set of forecast sensor data into the first set of forecast sensor data. Accordingly, in this example, the computer system can generate forecast sensor data according to operational states and/or operational state changes (e.g., transitional states) of the refrigeration component.

Therefore, by leveraging historical patterns and/or correlations between sensor data associated with the refrigeration component to forecast future sensor data for the refrigeration component, the computer system can forecast future behavior and/or activity of the refrigeration component to thereby detect instances of deviation from nominal behavior and/or activity as further described below.

### 5.3.1 Variation: Timeseries Prediction Model

In one variation, the computer system can generate the set of forecast sensor data based on correlations between series of historical sensor data and temporal patterns within series of historical sensor data.

In particular, in this variation, the computer system can: derive a first set of correlations between series of historical sensor data in a corpus of historical sensor data; derive a set of temporal patterns within the series of historical sensor data; and compile the set of correlations and the set of temporal patterns in a timeseries prediction model configured to forecast timeseries of future sensor data based on past and current sensor data. For example, the computer system can derive a correlation between increasing temperature values—in a series of temperature readings—from a sensor within a refrigeration volume and decreasing pressure values—in a series of pressure readings—from a pressure sensor within a compressor, which indicates a possible compressor failure. In another example, the computer system can derive a temporal pattern of periodic temperature fluctuations between a temperature maximum and a temperature minimum associated with cooling cycles of the refrigeration system.

In one implementation, the computer system can: derive a second set of correlations between the series of historical sensor data and a set of labels indicating normal or anomalous operation of the refrigeration system; and compile the second set of correlations in a timeseries, anomaly, and root cause prediction model configured to forecast timeseries of sensor data based on past and current sensor data and predict future anomalies and associated root causes. In one example, the computer system can derive a correlation between a random temperature fluctuation within a target range and a normal operation of the refrigeration system. In another example, the computer system can derive a correlation between: an increase in power consumption of the refrigeration system above a threshold; and a diagnostic work order request specifying a mechanical degradation (e.g., motor degradation) of a fan of the refrigeration system. Based on this correlation and temporal patterns, during execution of the timeseries prediction model, the computer system can detect a future anomaly in refrigeration system performance—based on the forecast timeseries of sensor data—in response to detecting that the power consumption of the refrigeration system exceeds the threshold.

In one implementation, the computer system can derive the correlations and temporal patterns by implementing gradient descent techniques. For example, the computer system can minimize a loss function to penalize forecast errors and incorrect anomaly and maintenance predictions (or erroneous correlations and temporal patterns) and configure the model to generate timeseries forecasts approximating actual values output by the refrigeration system and predictions approximating the labels.

### 5.3.2 Timeseries Prediction Model Deployment

Generally, the computer system can: access a corpus of past and current sensor data of the refrigeration system; and execute the timeseries prediction model to generate a forecast timeseries of sensor data for a set of sensors installed in the refrigeration system based on the corpus of past and current sensor data.

In one example, at a first time, the computer system can access a corpus of sensor data: including a first timeseries of temperature values representing temperatures within the refrigeration volume, a second timeseries of pressure values representing compressor pressures, and a third timeseries of energy values representing energy consumption of the refrigeration unit; and spanning a first time window preceding the first time. Based on this corpus of sensor data, the computer system can output the forecast timeseries of sensor data: including a fourth timeseries of temperature values representing future temperatures within the refrigeration volume, a fifth timeseries of pressure values representing future compressor pressures, and a sixth timeseries of energy values representing future energy consumption of the refrigeration unit; and spanning a second time window succeeding the first time. Accordingly, the computer system can: continuously receive real-time data from sensors across the refrigeration units; and continuously predict a next set of data points (e.g., sliding window) based on the most recent historical data.

In one implementation, the computer system can execute the timeseries, anomaly, and root cause prediction model to—based on the corpus of past and current sensor data—generate the forecast timeseries of sensor data, detect a future anomaly in the operation of the refrigeration system, and predict a root cause (e.g., failure mode of the refrigeration system) of the future anomaly. Accordingly, the computer system can execute the timeseries, anomaly, and root cause prediction model to predict future anomalies in operation of the refrigeration system, such as performance decreases, refrigerant leaks, and component failures.

### 5.4 Anomaly Detection+Root Cause Analysis

Generally, the computer system can: detect a deviation in a set of timeseries sensor data for the refrigeration system; and characterize the deviation as an anomaly. Furthermore, the computer system can: detect a refrigeration component as a root cause of the anomaly; and flag the refrigeration component for inspection prior to onset of the anomaly.

In particular, the computer system can: detect a set of deviations in sets of forecast sensor data associated with a subset of refrigeration components, the subset of refrigeration components functionally dependent (e.g., connected via refrigerant flow, thermodynamically dependent) on refrigeration components in the subset of refrigeration components; detect a first deviation in a first set of forecast sensor data, the first deviation occurring temporally prior to deviations in the set of deviations; detect a first refrigeration component associated with the first set of forecast sensor data; and associate the first refrigeration component as a root cause of the set of deviations. For example, the computer system can calculate a confidence score for identification of the first refrigeration component as a root cause of the set of deviations based on temporal similarity of the set of deviations.

In one implementation, the computer system can: access a corpus of timeseries sensor data captured by the set of sensors, associated with the refrigeration system; for each operational state in the set of operational states and based on the corpus of timeseries sensor data, derive a predicted behavior curve representing expected behavior of refrigeration components in the refrigeration system in the operational state; and detect the first deviation from the predicted behavior curve in the first set of forecast sensor data.

In one implementation, the computer system can detect the first refrigeration component as a root cause of the anomaly based on downstream behavior of refrigeration components functionally connected to the first refrigeration component. For example, the computer system can: access a first subset of forecast sensor data associated with the first refrigeration component; access a second subset of forecast sensor data associated with a second refrigeration component; and access a third subset of forecast sensor data associated with a third refrigeration component. The computer system can then: detect the first deviation in the first subset of forecast sensor data associated with the first refrigeration component; detect a second deviation in the second subset of forecast sensor data associated with the second refrigeration component functionally connected to the first refrigeration component based on the set of connections between refrigeration components, the second deviation occurring temporally subsequent the first deviation; and detect a third deviation in the third subset of forecast sensor data associated with the third refrigeration component functionally connected to the first refrigeration component and the second refrigeration component based on the set of connections between refrigeration components, the third deviation occurring temporally subsequent the second deviation.

In one implementation, the computer system can: derive a set of operational states of the refrigeration system, the set of operational states representing combinations of actuator states of the set of refrigeration components; detect a first combination of actuator states, represented by a first operational state in the set of operational states, associated with the first set of forecast sensor data; predict a future onset of the first combination of actuator states based on the first set of forecast sensor data; and flag the future onset of the first combination of actuator states for investigation. For example, the computer system can: detect a set of operational states of the refrigeration component based on state changes of the refrigeration component represented in the set of timeseries sensor data; and detect the first deviation in a first set of forecast sensor data associated with a first operational state, in the set of operational states, for the first refrigeration component.

Therefore, in the foregoing implementations, the computer system can detect deviations—such as from the operational state of the refrigeration system—in forecast sensor data to thereby detect instances of future anomalous behavior of the refrigeration system.

### 5.5 Actuator Toggling

In one variation, the computer system can access additional targeted timeseries sensor data from the refrigeration system based on triggering oscillation of actuators in the set of actuators.

For example, the computer system can: detect a first actuator, in the set of actuators, associated with the first refrigeration component, such as in response to detecting the first refrigeration component as associated with the first deviation; trigger the first actuator to cycle through a series of actuator positions during a target time interval (e.g., an idle period of the refrigeration system, during off-hours of the refrigeration system); access a second set of timeseries sensor data captured during the target time interval; and generate a second set of forecast sensor data representing predicted behavior of the refrigeration system based on the second set of timeseries sensor data and the set of refrigeration system rules. Therefore, in this example, the computer system can detect the first refrigeration component as the root cause of the first deviation in response to detecting a second deviation, analogous to the first deviation, in the second set of forecast sensor data.

In a similar example, the computer system can: detect a second actuator, in the set of actuators, associated with a second refrigeration component thermodynamically dependent on the first refrigeration component; trigger the second actuator to cycle through a second series of actuator positions during a second time interval succeeding the target time interval; access a third set of timeseries sensor data captured during the second time interval; generate a third set of forecast sensor data representing predicted behavior of the refrigeration system based on the third set of timeseries sensor data and the set of refrigeration system rules; and detect the first refrigeration component as the root cause of the first deviation in response to detecting a third deviation, analogous to the first deviation, in the third set of forecast sensor data.

In particular, the computer system can: for the first operational state in the set of operational states, calculate a confidence score, proportional to a resolution of the segment of timeseries sensor data, for detection of the first refrigeration component as the root cause of the first anomaly; and, in response to the confidence score falling below a threshold confidence score, implement methods and techniques as described herein to trigger the first actuator to cycle through the series of positions.

Accordingly, in the foregoing implementation, the computer system can detect the first refrigeration component as a root cause of the deviation in response to detecting downstream (e.g., temporally downstream, thermodynamically downstream) deviations, based on actuator oscillation, in refrigeration components thermodynamically dependent on the first refrigeration component. Additionally, the computer system can opportunistically access additional timeseries sensor data from the refrigeration system based on automatic toggling of the set of actuators of the refrigeration system to enable the set of sensors to collect targeted timeseries sensor data, such as responsive to calculating a confidence score falling below a threshold confidence score.

### 5.6 Variation: Anomaly Detection and Root-cause Analysis Modules

In one implementation the computer system can execute an anomaly detection module (e.g., extant refrigeration system-specific or generic anomaly detection module)—configured to detect current anomalies based on current refrigeration system sensor data—to detect a future anomaly based on the forecast timeseries of sensor data output by the timeseries prediction model.

For example, the computer system can: access an anomaly detection model; serve a first set of forecast sensor data associated with the first deviation to the anomaly detection model; and receive identification of the first deviation as the first anomaly from the anomaly detection model. In this example, the computer system can additionally:
access a root cause prediction model; serve the set of forecast sensor data and the first deviation to the root cause prediction model; and receive identification of the first refrigeration component as a root cause of the deviation from the root cause prediction model.

Accordingly, in the foregoing implementations, the computer system can implement machine learning (e.g., an artificial intelligence model) to detect anomalies and root causes of these anomalies in forecast sensor data for the refrigeration system.

In one implementation, the computer system can implement the anomaly detection module representing a set of heuristics (e.g., rule-based heuristics) for detecting anomalies based on current sensor data. In one example, the anomaly detection module can include rules for flagging temperature values that are more than two standard deviations from a mean value as anomalous. In another example, the anomaly detection module can include rules for flagging a value as anomalous in response to the value falling outside of a pre-defined range of values representing normal refrigeration system operation.

In one implementation the computer system can execute a root cause analysis module (e.g., extant refrigeration system-specific or generic root cause analysis module)—configured to detect current anomaly root causes based on current refrigeration system sensor data—to detect a future root cause of a future anomaly based on the forecast timeseries of sensor data output by the timeseries prediction model.

Accordingly, the computer system can implement the existing modules for anomaly detection and root cause analysis to detect future anomalies in the operation of the refrigeration system and predict root causes of these anomalies based on the forecast timeseries of sensor data output by the timeseries prediction model.

Therefore, the computer system can leverage existing modules for anomaly detection and root cause analysis to detect future anomalies in the operation of the refrigeration system, and predict their respective root causes, without necessitating construction, retraining, or deployment of new general or refrigeration system-specific anomaly detection and root cause analysis modules.

### 6. Preventative Maintenance Scheduling

Generally, the computer system can: flag a refrigeration component for inspection in response to detection of an anomaly in forecast sensor data for the refrigeration component; and schedule preventative maintenance for this refrigeration component prior to onset of the anomaly.

In one implementation, the computer system can: associate the first anomaly with a first state of the refrigeration component; predict onset of the first state according to the first set of forecast sensor data, such as an onset time of the anomaly; and flag the first refrigeration component for inspection prior to predicted onset of the first state according to the first set of forecast sensor data.

Additionally or alternatively, for each operational state in the set of operational states of a refrigeration component, the computer system can: generate a subset of forecast sensor data; aggregate the subset of forecast sensor data into the first set of forecast sensor data; detect the first deviation in a first subset of forecast sensor data associated with a first operational state in the set of operational states; predict onset of the first state according to the first subset of forecast sensor data; and flag the first refrigeration component for inspection prior to predicted onset of the first operational state according to the first subset of forecast sensor data.

In another implementation, the computer system can access a maintenance schedule defining a first scheduled maintenance visit at a first time and a second scheduled maintenance visit at a second time; generate a work order specifying inspection of the first refrigeration component; and, in response to detecting predicted onset of the first deviation occurring subsequent to the first scheduled maintenance visit and preceding the second scheduled maintenance visit, populate the maintenance schedule with the first work order specifying the first scheduled maintenance visit.

In particular, the computer system can generate the work order specifying resource consumption (e.g., repair duration, technician availability, refrigeration component accessibility, replacement part availability, lead time) of the preventative maintenance for the first refrigeration component. For example, the computer system can: calculate a predicted repair lead time for the first refrigeration component based on the first deviation; access a technician availability schedule defining time intervals associated with technicians qualified to repair the first refrigeration component; derive a target repair interval for the first refrigeration component based on the predicted repair lead time and the technician availability schedule; and generating a work order specifying a segment of forecast sensor data, in the first set of forecast sensor data, indicating the first deviation, characterization of the first deviation as the first anomaly, and identification of the first refrigeration component as the root cause of the first anomaly; and populate a maintenance schedule with the work order for the target repair interval.

In this implementation, the computer system can additionally: detect a first scheduled maintenance visit in the maintenance schedule; detect a second scheduled maintenance visit, succeeding the first scheduled maintenance visit, in the maintenance schedule; and populate the first scheduled maintenance visit in the maintenance schedule with the work order in response to the second scheduled maintenance visit succeeding predicted onset of the first deviation. Additionally or alternatively, the computer system can: accessing the maintenance schedule associated with the refrigeration system; and, in response to detecting absence of a future scheduled maintenance visit prior to predicted onset of the first deviation according to the first set of forecast sensor data, schedule a first future maintenance visit specifying the work order for the target repair interval.

In one implementation, the computer system can: detect the future anomaly based on the forecast timeseries of sensor data; access the first time of the future anomaly; access the maintenance schedule for the refrigeration system; and, in response to detecting an existing work order request, scheduled for a time preceding the first time of the future anomaly, populate the existing work order request with the report of the future anomaly. Accordingly, in response to predicting a deviation from normal operation of the refrigeration system, the computer system can autonomously update an existing, regularly scheduled work order request with information about the future anomaly to prompt the technician, assigned to the existing work order request, to address the future anomaly.

In particular, the computer system can: access a maintenance schedule for the refrigeration system in Block S175; detect a target time period, indicated by the maintenance schedule, for maintenance of the refrigeration system, the target time period occurring prior to predicted onset of the first anomaly according to the first set of forecast sensor data; generate a first work order specifying inspection of the first refrigeration component, based on the first anomaly, during the target time period in Block S172; and populate the maintenance schedule with the first work order indicating the target time period in Block S176.

Accordingly, the computer system can integrate with a preexisting maintenance schedule for the refrigeration system by generating and injecting work orders for refrigeration components predicted to exhibit future anomalies prior to onset of these anomalies.

In addition, in response to detecting an absence of a work order request preceding the anomaly in the maintenance schedule, the computer system can: generate a new work order request scheduled for a time preceding the first time of the future anomaly; populate the new work order request with the report of the future anomaly; and serve the work order request to the operator of the refrigeration system or to a maintenance crew tasked with maintaining the refrigeration system. Thus, the computer system can autonomously schedule work order requests for maintaining the refrigeration system.

In another implementation, the computer system can: predict a future anomaly in the operation of the refrigeration system occurring at a first time based on the first forecast timeseries of sensor data; access a set of anomaly characteristics of the future anomaly based on the first forecast timeseries of sensor data; and schedule preventative maintenance for the refrigeration system based on the set of anomaly characteristics of the future anomaly. More specifically, the computer system can characterize the future anomaly based on a segment of the first forecast timeseries of sensor data, overlapping the future anomaly. For example, based on the segment of the forecast timeseries of sensor data—representing anomalous readings from the set of sensors installed in the refrigeration system—the computer system can access and/or calculate the set of anomaly characteristics including: a certainty score (e.g., confidence interval) for the anomaly; a severity score (e.g., residual) for the anomaly; a time of the occurrence of the anomaly; a root cause of the anomaly (e.g., component failure, refrigerant leak); and a consequence of the anomaly (e.g., degradation in refrigeration system performance, loss of product stored in the refrigeration system).

Based on the set of anomaly characteristics, the computer system can schedule the preventative maintenance for the refrigeration system. In one implementation, based on the set of characteristics of the future anomaly, the computer system can generate a report describing the future anomaly, the report including: a written description of the anomaly; a numerical description of the anomaly, a description of the predicted root cause of the anomaly; a list of predicted replacement components for the preventative maintenance; and/or a description of a possible consequence of the anomaly. The computer system can then: populate the work order request for the refrigeration system with the report of the future anomaly; link the work order request with a type of maintenance technician requested to perform preventative maintenance on the refrigeration system; and link the work order request with a target time for filling the work order request. The computer system can then serve the work order request to an operator of the refrigeration system or directly to a maintenance crew tasked with maintaining the refrigeration system. Therefore, the computer system can leverage the forecast timeseries of sensor data to predict a future deviation from the normal operation of the refrigeration system and automatically schedule preventative maintenance for the refrigeration system to prevent the deviation from the normal operation or to remedy the root cause of the deviation and prevent a possible refrigeration system failure or performance degradation associated with the deviation.

In one implementation, the computer system can: detect the future anomaly based on the forecast timeseries of sensor data; and calculate a first confidence score for the future anomaly, the confidence score representing a likelihood that the anomalous value (or a set of values) represents a deviation from the normal operation of the refrigeration system. In response to the confidence score exceeding a threshold confidence score, the computer system can schedule a work order request to address the future anomaly. Accordingly, the computer system can schedule the work order request for the refrigeration system in response to the high certainty that future operation of the refrigeration system will deviate from the normal operation.

In one implementation, the computer system can: detect the future anomaly based on the forecast timeseries of sensor data; and calculate a severity score for the future anomaly, the severity score proportional to the deviation (e.g., residual) of the anomalous value from a value representing the normal operation of the refrigeration system. In response to the severity score exceeding a threshold severity, the computer system can schedule a work order request to address the future anomaly. Accordingly, the computer system can schedule the work order request in response to a severe future deviation from the normal operation of the refrigeration system.

In one implementation, the computer system can: detect the future anomaly based on the forecast timeseries of sensor data; predict a first root cause of the future anomaly; estimate operational impact of the future anomaly, the operational impact representing operational consequences, such as system performance, reliability, or downtime of not addressing the anomaly; estimate the resources associated with preventative maintenance for the future anomaly, the resources including replacement components, technician labor, and/or refrigeration system downtime; and, in response to the impact of not addressing the future anomaly exceeding the resources associated with preventative maintenance, schedule the work order request to address the future anomaly.

In one implementation, the computer system can schedule a work order request for a future anomaly based on technician availability—impacted by other work order requests, weekends, and holidays—and a predicted time of a future occurrence of the anomaly. For example, the computer system can: detect a technician with a skill set that matches a skill set for addressing the anomaly; access availability of the technician; and schedule the work order request for a time that overlaps technician availability and occurrence of the anomaly in the refrigeration system.

In one implementation, the computer system can schedule a work order request for a future anomaly based on availability of replacement components. For example, the computer system can: detect a replacement component associated with the anomaly; access availability of the replacement component (e.g., an estimated duration of shipping the component to the facility); and schedule the work order request for a time that overlaps availability of the replacement component and occurrence of the anomaly in the refrigeration system.

Therefore, the computer system can automatically schedule work order requests for the system such that the refrigeration system maintenance aligns with the availability of resources and personnel, ensuring timely resolution of future anomalies while minimizing operational disruption.

### 6.1 Variation: Compliance Document Generation/augmentation

In one variation, the computer system can implement methods and techniques as described herein to generation compliance and regulatory documents. For example, in response to detecting an anomaly (e.g., a leak) within the refrigeration system, the computer system can: generate a compliance document and/or populate a template compliance document, such as an EPA and/or CARB compliance document; and serve the compliance document to the operator portal. Similarly, the computer system can generate compliance documents representing refrigeration system emissions (e.g., Scope 1 emissions, Scope 2 emissions).

### 7. Prioritizing Anomalies+Triage

In one implementation, the computer system can: detect a first future anomaly based on the forecast timeseries of sensor data, the first future anomaly occurring at a first time (e.g., predicted future time); detect a second future anomaly occurring at a second time (e.g., predicted future time), succeeding the first time, based on the forecast timeseries of sensor data; estimate a first impact associated with the first future anomaly, the first impact representing operational consequences of not addressing the root cause of the first future anomaly in the refrigeration system; estimate a second impact associated with the second future anomaly, the second impact representing operational consequences of not addressing the second anomaly in the refrigeration system; and, in response to the second impact exceeding the first impact, scheduling a first work order request for addressing the second future anomaly for a third time and scheduling a second work order request for addressing the first future anomaly for a fourth time, succeeding the third time.

For example, the computer system can: generate a first work order for the first refrigeration component based on the first anomaly in Block S172; generate a second work order for the second refrigeration component based on the second anomaly in Block S172; calculate a first risk score for the first refrigeration component based on the first anomaly in Block S174; calculate a second risk score for the second refrigeration component based on the second anomaly in Block S174; and populate a maintenance schedule for the refrigeration system with the work order, the maintenance schedule specifying completion of the first work order prior to the second work order in response to the first risk score exceeding the second risk score in Block S176.

For example, the computer system can calculate the first risk score proportional to a predicted operational risk associated with the anomaly.

Additionally or alternatively, the computer system can: calculate a first risk score for the first refrigeration component based on the first anomaly; in response to the first risk score exceeding a threshold risk score, generate a first work order for the first refrigeration component based on the first anomaly; and populate a maintenance schedule for the refrigeration system with the first work order, the maintenance schedule specifying completion of the first work order prior to predicted onset of the first anomaly.

In one implementation, the computer system can triage anomalies based on impact of the anomaly. For example, the computer system can calculate an impact score based on environmental impact (e.g., energy emissions, leak emissions) and/or operational impact to the refrigeration system.

Accordingly, in response to detecting that the second future anomaly is associated with a more operationally impactful issue in the refrigeration system than the first future anomaly, the computer system can prioritize scheduling a work order request for the second future anomaly. Therefore, the computer system can autonomously allocate resources to addressing anomalies associated with most impactful operational consequences.

### 8. Remote Anomaly Resolution

In one implementation, the computer system can: predict an anomaly resolution action for a future anomaly; and remotely trigger execution of the anomaly resolution action. For example, the computer system can remotely modify the daily start and end times of a defrost cycle in the controller of the refrigeration system to preemptively address the anomaly, such as by preventing ice buildup that could otherwise lead to system inefficiency or failure. Therefore, the computer system can automatically resolve certain anomalies.

### 9. Model Feedback

In one implementation, the computer system can automatically update (e.g., retrain, derive updated parameters) for the timeseries prediction and anomaly detection model (or the timeseries prediction model) based on newly labeled datasets generated based on new timeseries output by the set of sensors of the refrigeration system, anomalies present in these timeseries, anomaly resolution actions that were implemented, and associated outcomes of the anomaly resolution actions.

For example, the computer system can: access new timeseries output by the set of sensors of the refrigeration system; correlate the new timeseries with a corresponding timeseries predicted by the model; detect deviations of the predicted timeseries from the new timeseries; and generate a labeled timeseries indicating false predictions (e.g., deviations of the predicted timeseries from the new timeseries). The computer system can then execute a retraining process on the timeseries prediction model based on the labeled timeseries to improve accuracy of the timeseries forecast by this model. In another example, based on feedback from a maintenance technician—received after completion of a work order request—the computer system can detect a false-positive anomaly. In response, the computer system can label this anomaly as false-positive and execute a retraining process on the timeseries prediction and anomaly detection model to improve anomaly prediction accuracy of this model.

Therefore, the computer system can continuously update the timeseries prediction and anomaly detection model (or the timeseries prediction model)—based on sensor data and/or feedback from completed work orders - to increase timeseries prediction accuracy, reduce false anomaly predictions (e.g., false positives, or false negatives), and enable the model to generate correct responses to anomalies.

### 10. Example: Data Pull Interface

In one example, the computer system can implement methods and techniques as described herein to generate forecast sensor data and detect refrigeration component exhibiting future anomalies in response to receiving a prompt from a user at a user interface, the prompt querying for forecast sensor data for the refrigeration system.

For example, the computer system can receive a first natural language prompt from a user at a user interface (e.g., a chat interface), the first natural language prompt specifying identification of future anomalies for refrigeration systems in a fleet of refrigeration systems. The computer system can then implement methods and techniques as described herein for each refrigeration system in the fleet of refrigeration systems to thereby automatically generate and schedule work orders for forecast anomalies for refrigeration system in the fleet of refrigeration systems.

Accordingly, in this example, the computer system can enable an operator—such as an operator overseeing hundreds of refrigeration systems in a fleet of refrigeration systems—to preemptively detect and mitigate operational failures within the fleet of refrigeration systems without needing to query each refrigeration system in the fleet of refrigeration systems.

### 11. Conclusion

The systems and methods described herein can be embodied and/or implemented at least in part as a machine configured to receive a computer-readable medium storing computer-readable instructions. The instructions can be executed by computer-executable components integrated with the application, applet, host, server, network, website, communication service, communication interface, hardware/firmware/software elements of a user computer or mobile device, wristband, smartphone, or any suitable combination thereof. Other systems and methods of the embodiment can be embodied and/or implemented at least in part as a machine configured to receive a computer-readable medium storing computer-readable instructions. The instructions can be executed by computer-executable components integrated by computer-executable components integrated with apparatuses and networks of the type described above. The computer-readable medium can be stored on any suitable computer readable media such as RAMs, ROMs, flash memory, EEPROMs, optical devices (CD or DVD), hard drives, floppy drives, or any suitable device. The computer-executable component can be a processor but any suitable dedicated hardware device can (alternatively or additionally) execute the instructions.

As a person skilled in the art will recognize from the previous detailed description and from the figures and claims, modifications and changes can be made to the embodiments of the invention without departing from the scope of this invention as defined in the following claims.

I claim:

1. A method comprising:
accessing a set of actuator position data captured during an initial time period from a set of actuators associated with a set of refrigeration components of a refrigeration system;
deriving a set of operational states of the refrigeration system based on combinations of actuator positions represented in the set of actuator position data;
accessing a first set of timeseries sensor data captured by a set of sensors, associated with the set of refrigeration components, during the initial time period;
accessing a set of refrigeration system rules specifying nominal thermodynamic behavior of refrigeration;
for each operational state in the set of operational states, generating a set of forecast sensor data representing predicted behavior of the refrigeration system in the operational state based on a segment of timeseries sensor data, representing the operational state, and the set of refrigeration system rules; and
for a first operational state in the set of operational states:
detecting a first deviation, in a first set of forecast sensor data representing predicted behavior of the refrigeration system in the first operational state, from nominal thermodynamic behavior of refrigeration components in the first operational state according to the set of refrigeration system rules;
in response to the first deviation exceeding a threshold deviation, characterizing the first deviation as a first anomaly;
accessing a graph of the refrigeration system representing thermodynamic connectivity between refrigeration components in the set of refrigeration components;
detecting a first refrigeration component, associated with the first anomaly according to the graph of the refrigeration system and the first set of forecast sensor data, as a root cause of the first anomaly; and
flagging the first refrigeration component for inspection prior to predicted onset of the first deviation according to the first set of forecast sensor data.

2. The method of claim 1:
wherein deriving the set of operational states of the refrigeration system based on combinations of actuator positions represented in the set of actuator position data comprises detecting combinations of actuator positions representing steady operating states of the refrigeration system based on temporal persistence of combinations of actuator positions; and
wherein detecting the first refrigeration component as the root cause comprises:
detecting a first temporal occurrence of the first deviation in the first set of forecast sensor data; and
detecting the first refrigeration component as the root cause in response to detecting the first refrigeration component associated with the first temporal occurrence of the first deviation.

3. The method of claim 1:
further comprising:
detecting combinations of actuator positions representing a set of operational state transitions between operating states of the refrigeration system; and
predicting a duration of each operational state in the set of operational states based on the first set of timeseries sensor data; and
wherein generating the set of forecast sensor data for each operational state in the set of operational states comprises, for each operational state in the set of operational states, generating the set of forecast sensor data based on the set of operational state transitions and the duration of the operational state.

4. The method of claim 1, wherein detecting the first refrigeration component as the root cause of the first anomaly comprises:
detecting a second refrigeration component thermodynamically dependent on the first refrigeration component according to the graph of the refrigeration system;
detecting a second deviation, in the first set of forecast sensor data, associated with the second refrigeration component and occurring temporally sequential to the first deviation;
detecting correspondence between the first deviation and the second deviation based on temporal propagation from the first deviation to the second deviation; and
detecting the first refrigeration component as the root cause of the first anomaly in response to detecting correspondence between the first deviation and the second deviation.

5. The method of claim 1, wherein generating the set of forecast sensor data for each operational state in the set of operational states comprises, for each operational state in the set of operational states:
calculating a confidence score proportional to a resolution of the segment of timeseries sensor data representing the operational state;
in response to the confidence score falling below a threshold confidence score, accessing a second set of timeseries sensor data associated with a second refrigeration system, the second refrigeration system corresponding to the first refrigeration system; and
generating the set of forecast sensor data based on:
a first segment of timeseries sensor data, representing the operational state, in the first set of timeseries sensor data;
the set of refrigeration system rules; and
a second segment of timeseries sensor data, representing the operational state, in the second set of timeseries sensor data.

6. The method of claim 1:
wherein deriving the set of operational states of the refrigeration system based on combinations of actuator positions represented in the set of actuator position data comprises:
detecting a first combination of actuator positions, in the set of actuator position data, comprising the first operational state;
detecting a second combination of actuator positions, in the set of actuator position data and distinct from the first combination of actuator positions, comprising a second operational state; and
detecting a third combination of actuator positions in the set of actuator position data representing a transition state from the first operational state to the second operational state; and
wherein generating the set of forecast sensor data for each operational state in the set of operational states comprises:
generating the first set of forecast sensor data, for the first operational state, based on a first segment of timeseries sensor data representing the first combination of actuator positions;
generating a second set of forecast sensor data, for the second operational state, based on a second segment of timeseries sensor data representing the second combination of actuator positions; and
generating a third set of forecast sensor data, for the transition state, based on a third segment of timeseries sensor data representing the third combination of actuator positions.

7. The method of claim 1:
further comprising, during the initial time period:
deriving a set of correlations between operational states in the set of operational states and the first set of timeseries sensor data; and
based on the set of correlations and the graph of the refrigeration system, generating a root cause detection model configured to identify refrigeration components as root causes of deviations based on forecast sensor data; and
wherein detecting the first refrigeration component as the root cause of the first anomaly comprises detecting the first refrigeration component as the root cause of the first anomaly based on the root cause detection model.

8. The method of claim 1, further comprising:
for a second operational state in the set of operational states:
detecting a second deviation, in a second set of forecast sensor data representing predicted behavior of the refrigeration system in the second operational state, from nominal thermodynamic behavior of refrigeration components in the second operational state according to the set of refrigeration system rules;
in response to the second deviation exceeding the threshold deviation, characterizing the second deviation as a second anomaly; and
detecting a second refrigeration component, associated with the second anomaly according to the graph of the refrigeration system and the second set of forecast sensor data, as a second root cause of the second anomaly;
calculating a first risk score for the first refrigeration component based on the first deviation;
calculating a second risk score for the second refrigeration component based on the second deviation;
generating a first work order specifying inspection of the first refrigeration component prior to inspection of the second refrigeration component in response to the first risk score exceeding the second risk score; and
populating a maintenance schedule with the first work order.

9. The method of claim 1:
further comprising accessing a maintenance schedule defining a first scheduled maintenance visit at a first future time and a second scheduled maintenance visit at a second future time;
wherein generating the set of forecast sensor data for each operational state in the set of operational states comprises, for each operational state in the set of operational states, generating the set of forecast sensor data representing predicted behavior of the refrigeration system in the operational state from a current time to the second future time corresponding to the second scheduled maintenance visit; and
wherein flagging the first refrigeration component for inspection prior to predicted onset of the first deviation according to the first set of forecast sensor data comprises:
generating a work order specifying inspection of the first refrigeration component; and
in response to detecting predicted onset of the first deviation occurring subsequent to the first scheduled maintenance visit and preceding the second scheduled maintenance visit, populating a maintenance schedule with the first work order specifying the first scheduled maintenance visit.

10. The method of claim 1, further comprising:
accessing a predicted repair lead time for the first refrigeration component based on the first deviation;
accessing a technician availability schedule defining time intervals associated with technicians qualified to repair the first refrigeration component;
deriving a target repair interval for the first refrigeration component based on the predicted repair lead time and the technician availability schedule;
generating a work order comprising:
a segment of forecast sensor data, in the first set of forecast sensor data, indicating the first deviation;
characterization of the first deviation as the first anomaly; and
identification of the first refrigeration component as the root cause of the first anomaly; and
populating a maintenance schedule with the work order for the target repair interval.

11. The method of claim 10, wherein populating the maintenance system with the work order for the target repair interval comprises:
accessing the maintenance schedule associated with the refrigeration system; and
in response to detecting absence of a future scheduled maintenance visit prior to predicted onset of the first deviation according to the first set of forecast sensor data, scheduling a first future maintenance visit specifying the work order for the target repair interval.

12. The method of claim 1:
further comprising:
for the first operational state in the set of operational states, calculating a confidence score, proportional to a resolution of the segment of timeseries sensor data, for detecting the first refrigeration component as the root cause of the first anomaly;
in response to the confidence score falling below a threshold confidence score, detecting a first actuator, in the set of actuators, associated with the first refrigeration component;
triggering the first actuator to cycle through a series of actuator positions during a target time interval;
accessing a second set of timeseries sensor data captured during the target time interval;
generating a second set of forecast sensor data representing predicted behavior of the refrigeration system based on the second set of timeseries sensor data and the set of refrigeration system rules; and
detecting a second deviation, analogous to the first deviation, in the second set of forecast sensor data; and
wherein flagging the first refrigeration component for inspection prior to predicted onset of the first deviation comprises flagging the first refrigeration component for inspection in response to detecting the second deviation, analogous to the first deviation, in the second set of forecast sensor data.

13. A method comprising, for a refrigeration system:
accessing a set of operational states of the refrigeration system based on combinations of actuator positions associated with the refrigeration system;
accessing a first set of timeseries sensor data captured by a set of sensors, associated with the refrigeration system, during an initial time period;
for each operational state in the set of operational states, generating a set of forecast sensor data representing predicted behavior of the refrigeration system in the operational state based on a segment of timeseries sensor data, in the first set of timeseries sensor data and representing the operational state, and a set of refrigeration system rules specifying nominal thermodynamic behavior of refrigeration components;
for a first operational state in the set of operational states, detecting a first deviation in a first set of forecast sensor data representing predicted behavior of the refrigeration system in the first operational state;
in response to the first deviation exceeding a threshold deviation:
accessing a graph of the refrigeration system representing thermodynamic connectivity between refrigeration components in the refrigeration system; and
detecting a first refrigeration component associated with the first deviation according to the graph of the refrigeration system and the first set of forecast sensor data;
detecting the first refrigeration component as a root cause of the first deviation in response to detecting propagation of deviations, analogous to the first deviation, in the first set of forecast sensor data and associated with refrigeration components thermodynamically connected to the first refrigeration component according to the graph of the refrigeration system; and
flagging the first refrigeration component for inspection prior to predicted onset of the first deviation according to the first set of forecast sensor data.

14. The method of claim 13, wherein detecting the first refrigeration component as the root cause of the first deviation comprises:
detecting a first actuator, in the set of actuators, associated with the first refrigeration component;
triggering the first actuator to cycle through a series of actuator positions during a target time interval;
accessing a second set of timeseries sensor data captured during the target time interval;
generating a second set of forecast sensor data representing predicted behavior of the refrigeration system based on the second set of timeseries sensor data and the set of refrigeration system rules; and
detecting the first refrigeration component as the root cause of the first deviation in response to detecting a second deviation, analogous to the first deviation, in the second set of forecast sensor data.

15. The method of claim 14:
further comprising:
detecting a second actuator, in the set of actuators, associated with a second refrigeration component thermodynamically dependent on the first refrigeration component;
triggering the second actuator to cycle through a second series of actuator positions during a second time interval succeeding the target time interval;
accessing a third set of timeseries sensor data captured during the second time interval; and
generating a third set of forecast sensor data representing predicted behavior of the refrigeration system based on the third set of timeseries sensor data and the set of refrigeration system rules; and
wherein detecting the first refrigeration component as the root cause of the first deviation comprises detecting the first refrigeration component as the root cause of the first deviation in response to detecting a third deviation, analogous to the first deviation, in the third set of forecast sensor data.

16. The method of claim 13:
further comprising, during the initial time period:
accessing a corpus of timeseries sensor data captured by the set of sensors, associated with the refrigeration system; and
for each operational state in the set of operational states and based on the corpus of timeseries sensor data, deriving a predicted behavior curve representing expected behavior of refrigeration components in the refrigeration system in the operational state; and
wherein detecting the first deviation comprises detecting the first deviation from the predicted behavior curve in the first set of forecast sensor data.

17. The method of claim 13, wherein detecting the first refrigeration component as the root cause of the first deviation comprises:
detecting a second refrigeration component thermodynamically dependent on the first refrigeration component according to the graph of the refrigeration system;
detecting a second deviation, in the first set of forecast sensor data, associated with the second refrigeration component and occurring temporally sequential to the first deviation;
detecting correspondence between the first deviation and the second deviation based on temporal propagation from the first deviation to the second deviation; and
detecting the first refrigeration component as the root cause of the first deviation in response to detecting correspondence between the first deviation and the second deviation.

18. The method of claim 13:
further comprising accessing a maintenance schedule defining a first scheduled maintenance visit at a first time and a second scheduled maintenance visit at a second time;
wherein generating the set of forecast sensor data for each operational state in the set of operational states comprises, for each operational state in the set of operational states, generating the set of forecast sensor data representing predicted behavior of the refrigeration system in the operational state from a current time to the second time corresponding to the second scheduled maintenance visit; and
wherein flagging the first refrigeration component for inspection prior to predicted onset of the first deviation according to the first set of forecast sensor data comprises:
generating a work order specifying inspection of the first refrigeration component; and
in response to detecting predicted onset of the first deviation occurring subsequent to the first scheduled maintenance visit and preceding the second scheduled maintenance visit, populating a maintenance schedule with the first work order specifying the first scheduled maintenance visit.

19. A method comprising:
accessing a set of actuator position data captured during an initial time period from actuators associated with a set of refrigeration components;
deriving a set of states of the refrigeration system based on combinations of actuator positions represented in the set of actuator position data, the set of states comprising:
a set of operational states of the refrigeration system; and
a set of transition states representing transitions between operational states;
accessing a first set of timeseries sensor data captured by a set of sensors, associated with a set of refrigeration components in a refrigeration system, during an initial time period;
accessing a set of refrigeration system rules specifying nominal thermodynamic behavior of refrigeration components during transitions between operational states;
for each state in the set of states:
extracting a segment of timeseries sensor data from the first set of timeseries sensor data, the segment of timeseries sensor data representing the state; and
generating a set of forecast sensor data, representing predicted behavior of the refrigeration system, based on the segment of timeseries sensor data and the set of refrigeration system rules;
detecting a first deviation in a first set of forecast sensor data representing predicted behavior of the refrigeration system in a first transition state in the set of transition states; and
in response to the first deviation exceeding a threshold deviation:
accessing a graph of the refrigeration system representing connectivity between refrigeration components in the set of refrigeration components;
detecting a first refrigeration component associated with the first deviation according to the graph of the refrigeration system and the first set of forecast sensor data;
identifying the first refrigeration component as a root cause of the first deviation; and
flagging the first refrigeration component for inspection prior to predicted onset of the first deviation according to the first set of forecast sensor data.

20. The method of claim 19, wherein identifying the first refrigeration component as the root cause of the first deviation comprises:
detecting a first actuator, in the set of actuators, associated with the first refrigeration component;
triggering the first actuator to cycle through a series of actuator positions during a target time interval;
accessing a second set of timeseries sensor data captured during the target time interval; and
generating a second set of forecast sensor data representing predicted behavior of the refrigeration system based on the second set of timeseries sensor data and the set of refrigeration system rules; and
detecting the first refrigeration component as the root cause of the first deviation in response to detecting a second deviation, analogous to the first deviation, in the second set of forecast sensor data.
